(19) United States
(12) Patent Application Publication
(10) Pub. No.: US 2016/0276135 A1
(43) Pub. Date: Sep. 22, 2016

(54) SUBSTRATE PROCESSING APPARATUS

(71) Applicant: HITACHI KOKUSAI ELECTRIC INC., Tokyo (JP)

(72) Inventors: Tetsuo YAMAMOTO, Toyama-shi (JP); Kazuyuki TOYODA, Toyama-shi (JP); Shun MATSUI, Toyama-shi (JP)

(73) Assignee: HITACHI KOKUSAI ELECTRIC INC., Tokyo (JP)

(21) Appl. No.: 15/006,174

(22) Filed: Jan. 26, 2016

(30) Foreign Application Priority Data
Mar. 20, 2015 (JP) 2015-058325

(51) Int. Cl. H01J 37/32; C23C 16/455; C23C 16/50

(52) U.S. Cl. CPC H01J 37/3244; C23C 16/50; C23C 16/455; H01J 37/32009

(57) ABSTRACT

A substrate processing apparatus includes a substrate mounting table on which a substrate is mounted, a process chamber including the substrate mounting table, a gas supply unit configured to supply a gas into the process chamber, and a plasma generating unit configured to convert the gas supplied into the process chamber from the gas supply unit into a plasma state. The plasma generating unit includes a plasma generating chamber configured to serve as a flow path of the gas supplied into the process chamber from the gas supply unit, and a plasma generating conductor configured by a conductor disposed to surround the plasma generating chamber. The plasma generating conductor includes a plurality of main conductor parts extending along a mainstream direction of the gas within the plasma generating chamber, and a plurality of connection conductor parts configured to electrically connect the plurality of main conductor parts with each other.

### CROSS-REFERENCE TO RELATED APPLICATION

This application is based upon and claims the benefit of priority from Japanese Patent Application No. 2015-058325, filed on Mar. 20, 2015, the entire contents of which are incorporated herein by reference.

### TECHNICAL FIELD

The present disclosure relates to a substrate processing apparatus.

### BACKGROUND

In general, a substrate processing apparatus that performs a process such as a film forming process or the like on a substrate such as a wafer is used in a process of manufacturing a semiconductor device. A process performed by the substrate processing apparatus may be, for example, a film forming process using an alternate supply method. In the film forming process using the alternate supply method, one cycle including a source gas supply process, a purge process, a reaction gas supply process, and a purge process is repeatedly performed on a substrate as a process target a predetermined number of times (n cycles) to form a film on the substrate. The substrate processing apparatus that performs such a film forming process supplies various gases (a source gas, a reaction gas, or a purge gas) onto a surface of a substrate as a process target from an upper side of the substrate in turn to allow the source gas and the reaction gas to be reacted on the surface of the substrate, thereby forming a film on the substrate. Further, in order to increase the efficient reaction with a source gas, when reaction gas is supplied, the corresponding reaction gas may be converted into plasma.

In such an apparatus, however, it is required to further increase usage efficiency of plasma and to enhance the film quality in some cases.

### SUMMARY

The present disclosure provides some embodiments of a technique of forming a high quality film using plasma.

According to one aspect of the present disclosure, there is provided a substrate processing apparatus, including: a substrate mounting table on which a substrate is mounted; a process chamber including the substrate mounting table; a gas supply unit configured to supply a gas into the process chamber; and a plasma generating unit configured to convert the gas supplied into the process chamber from the gas supply unit into a plasma state, wherein the plasma generating unit includes: a plasma generating chamber configured to serve as a flow path of the gas supplied into the process chamber from the gas supply unit; and a plasma generating conductor formed of a conductor disposed to surround the plasma generating chamber, and wherein the plasma generating conductor includes: a plurality of main conductor parts extending along a mainstream direction of the gas within the plasma generating chamber; and a plurality of connection conductor parts configured to electrically connect the plurality of main conductor parts with each other.

### BRIEF DESCRIPTION OF THE DRAWINGS

FIGS. 1A and 1B are schematic diagrams illustrating schematic configurations of an ICP coil according to the present disclosure and an ICP coil of a comparative example, wherein FIG. 1A is a diagram illustrating a schematic configuration example of a first embodiment of the present disclosure, and FIG. 1B is a diagram illustrating a schematic configuration example of the comparative example.

FIG. 2 is a conceptual view illustrating a schematic configuration example of a major part of a substrate processing apparatus according to a first embodiment of the present disclosure.

FIGS. 3A and 3B are views illustrating a configuration example of a gas supply unit used in the substrate processing apparatus according to the first embodiment of the present disclosure, wherein FIG. 3A is a perspective view thereof and FIG. 3B is a side cross-sectional view thereof.

FIG. 4 is a side sectional view taken along line A-A of FIG. 2, illustrating a specific configuration example of a major part of the substrate processing apparatus according to the first embodiment of the present disclosure.

FIG. 5 is a side sectional view taken along line B-B of FIG. 2, illustrating a specific configuration example of a major part of the substrate processing apparatus according to the first embodiment of the present disclosure.

FIG. 6 is a plane view of a cross-section taken along line C-C of FIG. 4, illustrating a specific configuration example of a major part of the substrate processing apparatus according to the first embodiment of the present disclosure.

FIG. 7 is a plane view of a cross-section taken along line C-C of FIG. 4, illustrating another specific configuration example of a major part of the substrate processing apparatus according to the first embodiment of the present disclosure.

FIG. 8 is a conceptual view schematically illustrating a configuration example of a gas pipe in the substrate processing apparatus according to the first embodiment of the present disclosure.

FIGS. 9A and 9B are views illustrating a configuration example of a plasma generating unit (ICP coil) used in the substrate processing apparatus according to the first embodiment of the present disclosure, wherein FIG. 9A is a perspective view thereof and FIG. 9B is a side sectional view thereof.

FIG. 10 is a flowchart illustrating a substrate processing process according to the first embodiment of the present disclosure.

FIG. 11 is a flowchart illustrating details of a relative position movement processing operation performed in a film forming process of FIG. 10.

FIG. 12 is a flowchart illustrating details of a gas supply and exhaust processing operation performed in a film forming process of FIG. 10.

FIG. 13 is a schematic diagram illustrating a schematic configuration example of a plasma generating unit (ICP coil) used in a substrate processing apparatus according to a second embodiment of the present disclosure.

FIGS. 14A and 14B are schematic diagrams illustrating a schematic configuration example of a plasma generating unit (ICP coil) according to a third embodiment of the present disclosure.

FIG. 15 is a schematic diagram illustrating another configuration example of the plasma generating unit according to the third embodiment of the present disclosure.

FIG. 16 is a schematic diagram illustrating another configuration example of the plasma generating unit according to the third embodiment of the present disclosure.

FIGS. 17A and 17B are schematic diagrams illustrating a configuration example of a plasma generating unit (ICP coil) used in a s substrate processing apparatus according to a fourth embodiment of the present disclosure, in which FIG. 17A is a diagram illustrating an example thereof and FIG. 17B is a diagram illustrating another example thereof.

FIG. 18 is a side sectional view illustrating a schematic configuration example of a plasma generating unit (ICP coil) used in a substrate processing apparatus according to a fifth embodiment of the present disclosure.

### DETAILED DESCRIPTION

### First Embodiment of the Present Disclosure

Hereinafter, a first embodiment of the present disclosure will be described with reference to the drawings.

### (1) Outline of First Embodiment of Present Disclosure

First, an outline of a first embodiment of the present disclosure will be described in comparison to the related art.

In the first embodiment, a process is performed on a substrate using a single-wafer-type substrate processing apparatus. A substrate to be processed may be, for example, a semiconductor wafer substrate in which a semiconductor device is embedded (hereinafter, simply referred to as a “wafer”). Further, a process performed on the substrate may be an etching process, an ashing process, a film forming process, or the like, and in the first embodiment, in particular, the film forming process is performed by an alternate supply method.

In the film forming process performed by the alternate supply method, a source gas, a purge gas, a reaction gas, and a purge gas are sequentially supplied onto a surface of a substrate as a process target from an upper side of the substrate to allow the source gas and the reaction gas to react on the surface of the substrate to form a film on the substrate, and in addition, in order to enhance the efficiency of reaction with the source gas, when the reaction gas is supplied, the reaction gas is converted into plasma.

In converting the reaction gas into plasma, an inductively coupled method can be considered. This is because the inductively coupled method can easily obtain high density plasma, compared with a capacitively coupled method.

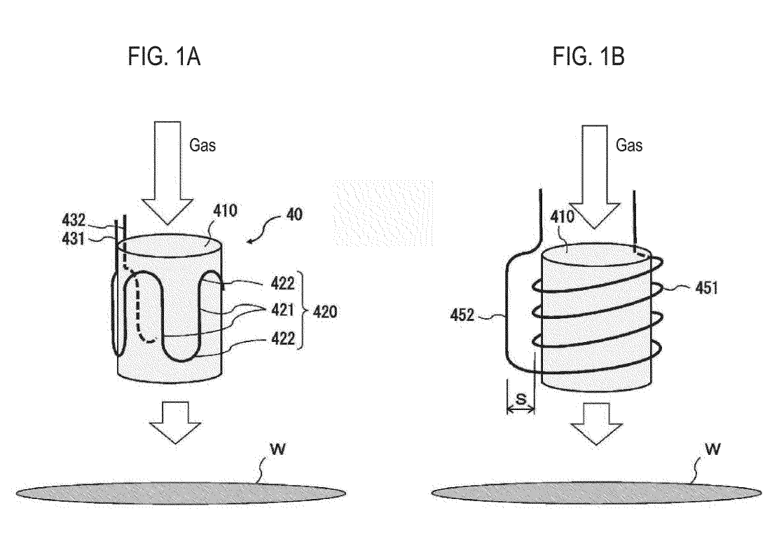

Here, a generation form of the inductively coupled plasma (hereinafter, simply referred to as “ICP”) in a comparative example will be described. FIG. 1B is a schematic diagram illustrating a schematic configuration of an ICP coil according to a comparative example. As illustrated in the example shown in the drawing, a coil 451 is spirally wound around a plasma generating chamber 410 through which a gas to be converted into plasma passes, and a large current having a high frequency is flown to the coil 451 in the comparative example. As the large current flows, a magnetic field is generated in the plasma generating chamber 410, thus generating the ICP.

However, in the single-wafer-type substrate processing apparatus, various gases (a source gas, a reaction gas, or a purge gas) are supplied onto a surface of a wafer W as a process target from an upper side of the wafer W. Specifically, the wafer W is moved to sequentially pass through a supply region of a source gas and a supply region of a reaction gas, and in order to prevent the source gas and the reaction gas from being mixed, a supply region of a purge gas is also disposed between the supply region of the source gas and the supply region of the reaction gas. Further, in each of the gas supply regions, various gases are supplied to the wafer W from an upper side of the wafer W. In the substrate processing apparatus having such a configuration, the coil 451 for converting a reaction gas into plasma is configured to receive power from an upper side thereof in order to avoid interference with other gas supply regions positioned adjacent to each other.

However, when power is supplied to the spiral coil 451 from the upper side of the spiral coil 451, a conductor 452 installed to extend upwardly from a lower end of the coil 451 is required and a sufficient space S needs to be secured between the conductor 452 and the coil 451. If the sufficient space S is not secured, a magnetic field generated by the coil 451 is canceled out by a magnetic field generated by the conductor 452, resulting in a negative influence such as non-uniformity of plasma generated within the plasma generating chamber 410. For this reason, in the ICP coil according to the comparative example, it may be difficult to convert the reaction gas into plasma in a space-saving manner, while maintaining high density of plasma.

In this regard, the inventors of the present application repeatedly studied the problem carefully and conceived an ICP coil having a novel configuration different from that of the comparative example. FIG. 1A is a schematic diagram illustrating a schematic configuration of an ICP coil according to a first embodiment of the present disclosure. The ICP coil of the example shown in the drawing serves as the plasma generating unit for converting a reaction gas supplied to a wafer W into plasma, and includes a plasma generating chamber 410 as a flow path through which a reaction gas to be converted into plasma passes and a plasma generating conductor 420 configured by a conductor disposed to surround the plasma generating chamber 410. That is, a reaction gas flowing within the plasma generating chamber 410 passes through the interior of an annular body formed by the plasma generating conductor 420.

The plasma generating conductor 420 has a plurality of main conductor parts 421 extending in a mainstream direction of a gas within the plasma generating chamber 410 and connection conductor parts 422 for electrically connecting the main conductor parts 421. That is, the conductor constituting the plasma generating conductor 420 includes conductor portions as the main conductor parts 421 and a conductor portion as the connection conductor parts 422.

The connection conductor parts 422 include a connection conductor part disposed in a position connecting lower ends of the main conductor parts 421 and a connection conductor part disposed in a position connecting upper ends of the main conductor parts 421. By having the main conductor parts 421 and the connection conductor parts 422 described above, the plasma generating conductor 420 is disposed to have a wave form waving in a mainstream direction of a gas within the plasma generating chamber 410.

An input conductor 431 configured to provide power to the plasma generating conductor 420 is connected to one main conductor part 421 among the plurality of main conductor parts 421, which is positioned in the conductor end of the plasma generating conductor 420. Further, an output conductor 432 for extracting power provided to the plasma generating conductor 420 is connected to another main conductor part 421 positioned in the conductor end of the plasma generating conductor 420. The input conductor 431 and the output conductor 432 are connected to a matcher (not shown) and a high-frequency power source (not shown).

In the ICP coil having such a configuration, in order to convert a reaction gas flowing within the plasma generating chamber 410 into plasma, a current having a high frequency is applied to the plasma generating conductor 420 through the input conductor 431 and the output conductor 432. When a current is applied, a magnetic field is generated around the plasma generating conductor 420. Here, the plasma generating conductor 420 is disposed to surround the plasma generating chamber 410 and is configured by the plurality of main conductor parts 421. That is, the plurality of main conductor parts 421 is arranged around the plasma generating chamber 410. Thus, when a current is applied to the plasma generating conductor 420, a composite magnetic field compounded from magnetic field by each of the main conductor parts 421 is formed within the plasma generating chamber 410, in a range of a region in which the plurality of main conductor parts 421 are disposed. When the reaction gas passes through the interior of the plasma generating chamber 410 with the composite magnetic field formed therein, the reaction gas is excited by the composite magnetic field so as to be converted into plasma. In this manner, the ICP coil according to the first embodiment converts a reaction gas passing through the interior of the plasma generating chamber 410 into plasma.

On the other hand, the input conductor 431 and the output conductor 432 for applying a current to the plasma generating conductor 420 are connected to the main conductor parts 421 positioned in the conductor end of the plasma generating conductor 420. That is, it is possible to dispose the input conductor 431 and the output conductor 432 upwardly from the main conductor parts 421 as they are. For this reason, unlike the comparative example (the ICP coil illustrated in FIG. 1B), in the ICP coil according to the first embodiment, there is no need to sufficiently secure a space S between the conductor 452 installed to extend upwardly from the lower end of the coil 451 and the coil 451, thus saving as much space as the space S compared with the comparative example. Further, when the plurality of main conductor parts 421 is equally disposed to surround the plasma generating chamber 410, there is no possibility that plasma is non-uniformly generated within the plasma generating chamber 410. In addition, since the reaction gas is converted into plasma by the inductively coupled method in which the composite magnetic field is formed within the plasma generating chamber 410, high density plasma can be easily obtained. That is, according to the ICP coil of the first embodiment, since the plasma generating conductor 420 has a novel configuration different from that of the comparative example, the reaction gas can be converted into plasma in a space saving manner while maintaining high plasma density.

### (2) Configuration of Substrate Processing Apparatus According to First Embodiment

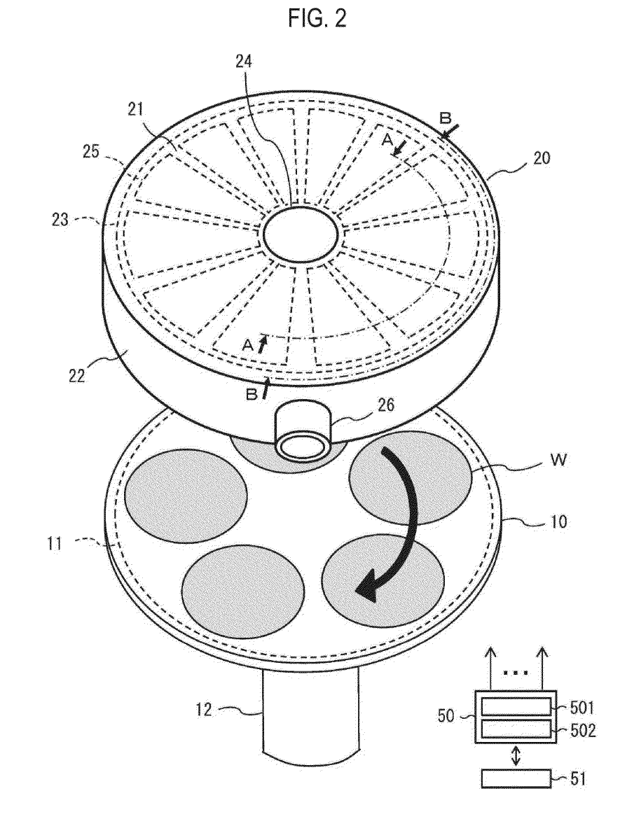

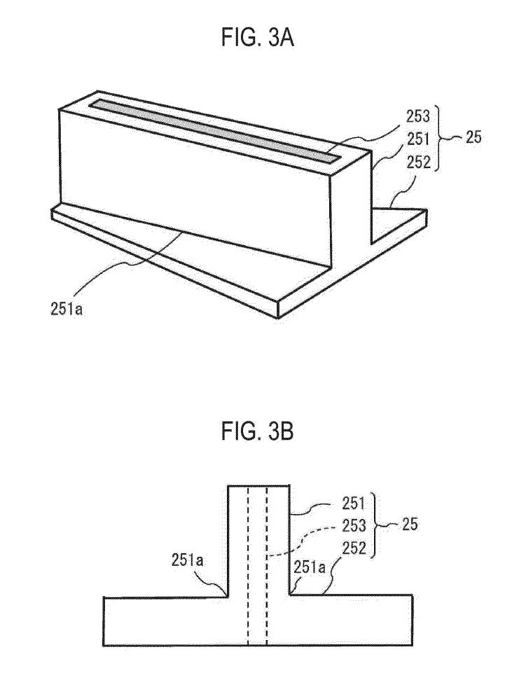

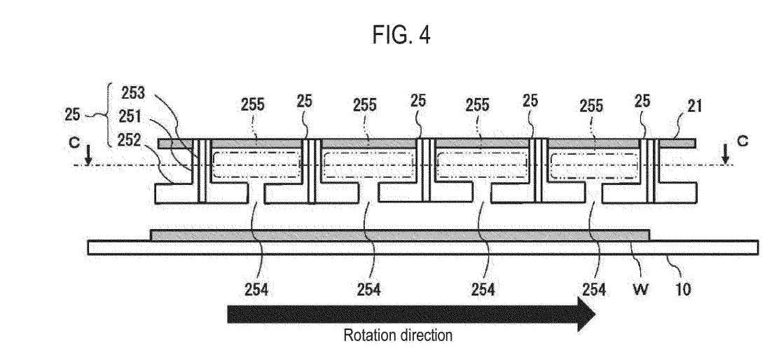

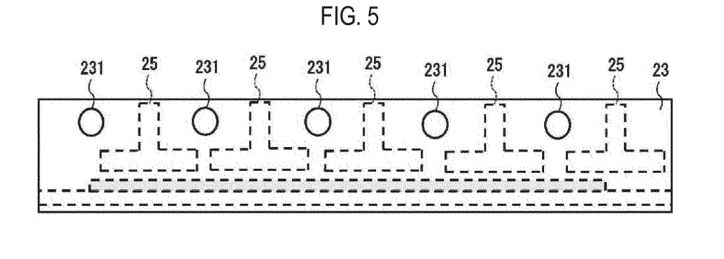

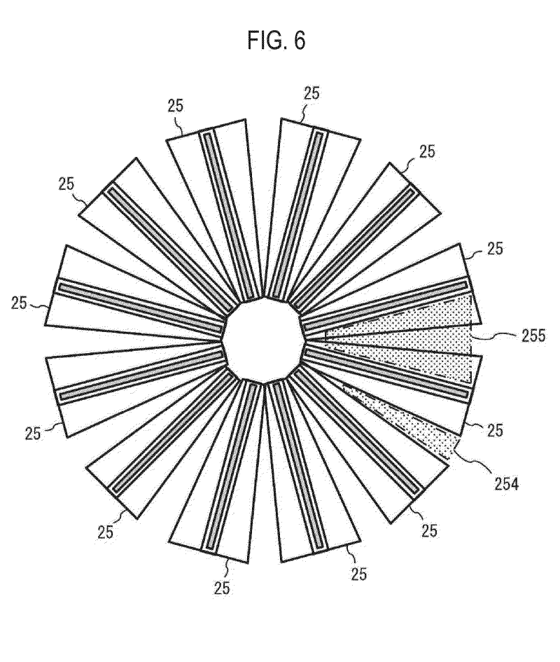

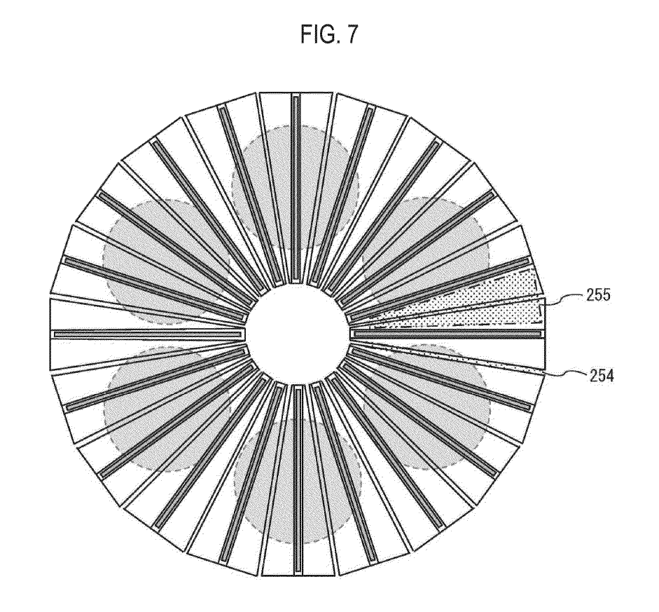

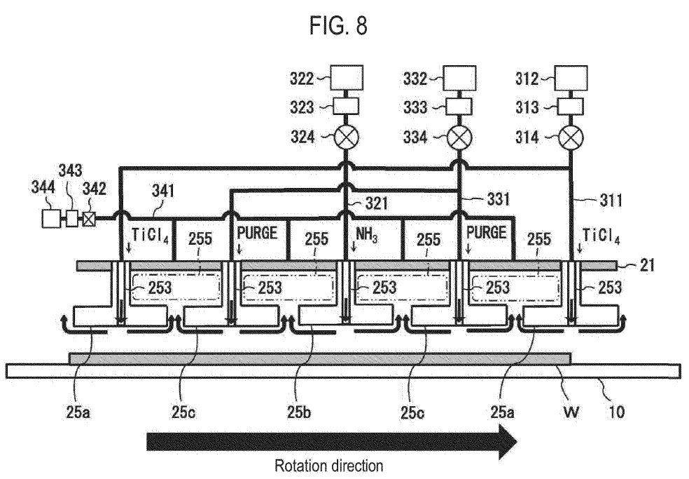

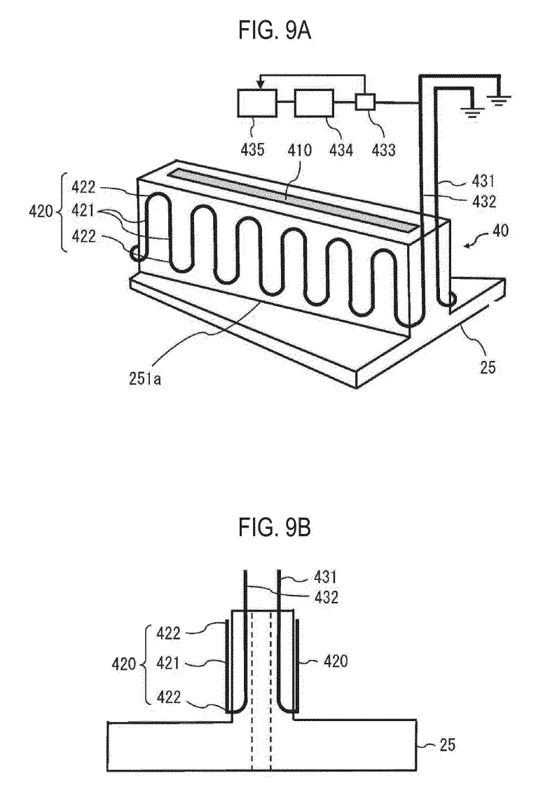

Hereinafter, a specific configuration of the substrate processing apparatus according to the first embodiment will be described with reference to FIGS. 2 to 9. FIG. 2 is a conceptual view illustrating a schematic configuration example of a major part of the substrate processing apparatus according to the first embodiment. FIGS. 3A and 3B are conceptual views illustrating a configuration example of a gas supply unit used in the substrate processing apparatus according to the first embodiment. FIG. 4 is a side sectional view taken along line A-A of FIG. 2. FIG. 5 is a side sectional view taken along line B-B of FIG. 2. FIG. 6 is a plane view of a cross-section taken along line C-C of FIG. 4. FIG. 7 is a plane view illustrating another configuration of a cross-section taken along line C-C of FIG. 4. FIG. 8 is a conceptual view schematically illustrating a configuration example of a gas pipe in the substrate processing apparatus according to the first embodiment. FIGS. 9A and 9B are conceptual views illustrating a configuration example of a plasma generating unit (ICP coil) used in the substrate processing apparatus according to the first embodiment.

### (Process Vessel)

The substrate processing apparatus described in the first embodiment has a process vessel (not shown). The process vessel is configured as an airtight vessel formed of a metal material such as aluminum (Al), stainless steel (SUS), or the like. Further, a substrate loading/unloading hole (not shown) is formed on a side surface of the process vessel, and a wafer is transferred through the substrate loading/unloading hole. Further, a gas exhaust system such as a vacuum pump (not shown) or a pressure controller (not shown) is connected to the process vessel, and the interior of the process vessel can be adjusted to a predetermined pressure using the gas exhaust system.

### (Substrate Mounting Table)

As illustrated in FIG. 2, a substrate mounting table 10 on which a wafer is mounted is installed within the process vessel. The substrate mounting table 10 has, for example, a disk shape, and is configured such that a plurality of wafers W is mounted on an upper surface (substrate mounting surface) thereof at an equal interval in a circumferential direction. Further, the substrate mounting table 10 includes a heater 11 embedded therein as a heating source, and the wafer W can be maintained at a predetermined temperature using the heater 11. Further, in the example shown in the drawing, a case in which five wafers W are mounted is illustrated, but the present disclosure is not limited thereto and the mounting number of wafers may be appropriately set. For example, when the mounting number of wafers is large, processing throughput can be enhanced, and when the mounting number of wafers is small, an increase of the substrate mounting table 10 in size can be avoided. Since the substrate mounting surface of the substrate mounting table 10 makes a direct contact with the wafer W, it may be made of a material such as, for example, quartz or alumina in some embodiments.

The substrate mounting table 10 is configured to rotate while a plurality of wafers W is mounted thereon. Specifically, the substrate mounting table 10 is connected to a rotation driving mechanism 12 whose rotational shaft is positioned in a central portion of the disk shape, and is rotated by the rotation driving mechanism 12. The rotation driving mechanism 12 may be configured by a rotary bearing configured to rotatably support the substrate mounting table 10 or a driving source represented by an electric motor.

Further, herein, the case in which the substrate mounting table 10 is configured to rotate is described by way of example, even a configuration where a cartridge head 20 described later is rotated is possible, as long as a relative position of each wafer W on the substrate mounting table 10 with the cartridge head 20 can be moved. In a configuration where the substrate mounting table 10 is rotatable, it is possible to avoid a complicated configuration of a gas pipe described later or the like, unlike the case in which the cartridge head 20 is rotated. In contrast, when the cartridge head 20 is configured to rotate, an inertial moment acting on the wafer W can be suppressed, compared with the case in which the substrate mounting table 10 is rotated, thereby increasing a rotational speed.

### (Cartridge Head)

Further, within the process vessel, the cartridge head 20 is installed above the substrate mounting table 10. The cartridge head 20 serves to supply various gases (a source gas, a reaction gas, or a purge gas) to the wafer W on the substrate mounting table 10 from the upper side of the wafer W, and to exhaust supplied various gases upwardly.

For the supply of the various gases from the upper side of the wafer W and the exhaust of the various gases upwardly, the cartridge head 20 includes a ceiling part 21 having a disk shape, a cylindrical external container part 22 downwardly extending from an edge portion of an outer peripheral end of the ceiling part 21, a cylindrical internal container part 23 disposed at an inner side of the external container part 22, a cylindrical central container part 24 disposed to correspond to a rotational shaft of the substrate mounting table 10, and a plurality of gas supply units 25 installed below the ceiling part 21 between the internal container part 23 and the central container part 24. Further, an exhaust port 26 that communicates with a space formed between the external container part 22 and the internal container part 23 is installed on the external container part 22. The ceiling part 21, the external container part 22, the internal container part 23, each of the gas supply units 25, and the exhaust port 26 constituting the cartridge head 20 are formed of a metal such as aluminum (Al), stainless steel (SUS) or the like.

Further, a case in which twelve gas supply units 25 are installed in the cartridge head 20 is illustrated as an example in the drawing, but an installation number of the gas supply units 25 is not limited thereto and may be appropriately set in consideration of the number of gas types supplied to the wafer W, processing throughput, or the like. In the case where, e.g., as described in detail later, a film forming process including a source gas supply process, a purge process, a reaction gas supply process, and a purge process as one cycle, is performed on the wafer W as a process target, the installation number of gas supply units 25 may be set to the multiple of 4 corresponding to each process. However, in order to enhance the processing throughput, a larger number of the gas supply units 25 may be installed in some embodiments.

### (Gas Supply Unit)

Here, each of the gas supply units 25 in the cartridge head 20 will be described in more detail.

The gas supply unit 25 forms a gas flow path when the supply of the various gases from the upper side of the wafer W and the exhaust of the various gases upwardly are performed with respect to the wafer W. For this, as illustrated in FIG. 3A, the gas supply unit 25 has a first member 251 having a rectangular shape and a second member 252 having a plate shape and attached to a lower side of the first member 251. The second member 252 has a planar shape having a width greater than that of a planar shape of the first member 251. Specifically, for example, while the first member 251 has a rectangular shape as a planar shape, the second member 252 has a fan shape or a trapezoid shape, as a planar shape, which becomes widened along a direction from one edge side of the first member 251 in a lengthwise direction toward the other edge side. As illustrated in FIG. 3B, by having the first member 251 and the second member 252, the gas supply unit 25 has corner portions 251a between the first member 251 and the second member 252 and an upwardly protruding convex shape, when viewed from one edge side in the lengthwise direction of the first member 251.

Further, as illustrated in FIGS. 3A and 3B, for example, the gas supply unit 25 has a gas supply path 253 formed as a through hole having a planar rectangular shape. The gas supply path 253 is formed by boring the first member 251 and the second member 252 in a penetrating manner, which serves as a gas flow path when a gas is supplied to the wafer W from the upper side of the wafer W. That is, the gas supply unit 25 includes the gas supply path 253 as a gas flow path, the first member 251 disposed to surround an upper portion of the gas supply path 253, and the second member 252 disposed to surround a lower portion of the gas supply path 253. Further, the first member 251 and the gas supply path 253 may not necessarily have a planar rectangular shape and may have any other shape (for example, an oval or fan shape).

As illustrated in FIG. 4, a plurality of gas supply units 25 configured in this manner is installed and used such that they are kept on the ceiling part 21 of the cartridge head 20 while being arranged at a predetermined interval. The plurality of gas supply units 25 is each disposed such that a lower surface of the second member 252 faces the wafer W on the substrate mounting table 10 and is parallel to the mounting surface of the wafer W on the substrate mounting table 10.

With such a disposition, an edge of the second member 252 of each of the mutually adjacent gas supply units 25 forms a portion of a gas exhaust hole 254 for exhausting gas supplied to the wafer W upwardly.

Further, in each of the mutually adjacent gas supply units 25, a wall surface of the first member 251 and an upper surface having a large width of the second member 252 forms a portion of an exhaust buffer chamber 255 as a space for retaining a gas which passes through the gas exhaust hole 254. More specifically, a ceiling surface of the exhaust buffer chamber 255 is formed by the ceiling part 21 of the cartridge head 20. A lower surface of the exhaust buffer chamber 255 is formed by an upper surface of the second member 252 of each of the mutually adjacent gas supply units 25. A sidewall surface of the exhaust buffer chamber 255 is formed by a wall surface of the first member 251 of each of the mutually adjacent gas supply units 25 and the internal container part 23 and the central container part 24 of the cartridge head 20.

Further, as illustrated in FIG. 5, in a portion of the internal container part 23 constituting the sidewall surface of the exhaust buffer chamber 255, an exhaust hole 231 for allowing the exhaust buffer chamber 255 to communicate with a space formed between the external container part 22 and the internal container part 23 is formed to correspond to each of the exhaust buffer chambers 255.

On the other hand, as already described above, the ceiling part 21 of the cartridge head 20 has a disk shape. Accordingly, as illustrated in FIG. 6, each of the plurality of gas supply units 25 kept on the ceiling part 21 is radially installed toward an outer peripheral side from a rotation center side of the substrate mounting table 10. With this configuration, each of the plurality of gas supply units 25 is arranged in a rotation circumferential direction of the substrate mounting table 10.

When each of the gas supply units 25 is radially disposed, the planar shape of the first member 251 of each of the gas supply units 25 is a rectangular shape, and thus, the exhaust buffer chamber 255 having a sidewall surface defined by the first member 251 has a planar shape which increases along a direction from the rotation center side of the substrate mounting table 10 toward the outer peripheral side. That is, the exhaust buffer chamber 255 is formed such that a size of the exhaust buffer chamber 255 in a rotation circumferential direction of the substrate mounting table 10 is gradually larger along a direction from the inner circumferential side to the outer peripheral side.

Further, each of the gas supply units 25 is disposed such that the second member 252 having a fan or trapezoid shape is widened along a direction from the rotation center side of the substrate mounting table 10 toward the outer peripheral side. Thus, the gas exhaust hole 254 formed to include an edge of the second member 252 also has a planar shape which is widened along a direction from the rotation center side of the substrate mounting table 10 toward the outer peripheral side.

However, the gas exhaust hole 254 may not necessarily have the planar shape widened along a direction from the rotation center side toward the outer peripheral side, but may be formed to have a slit shape having substantially the same width along a direction from the rotation center side toward the outer peripheral side, as illustrated in FIG. 7. This structure can make the exhaust conductance in the slit uniform over a region from the center of the process chamber to the outer periphery. Thus, when exhaust efficiency is set as described later, only the adjustment of the structure of the exhaust buffer chamber 255 needs to be considered without consideration of conductance of the exhaust hole 254, thereby facilitating adjustment of the exhaust efficiency of the entire process space.

### (Gas Supply/Exhaust System)

A gas supply/exhaust system described later is connected to the cartridge head 20 configured to include the gas supply units 25 described above in order to perform an upward supply/upward exhaust of various gases on the wafer W on the substrate mounting table 10, as illustrated in FIG. 8.

### (Process Gas Supply Unit)

A source gas supply pipe 311 is connected to the gas supply path 253 of at least one gas supply unit 25a among the plurality of gas supply units 25 constituting the cartridge head 20. A source gas supply source 312, a mass flow controller (MFC) 313 which is a flow rate controller (flow rate control unit), and a valve 314 which is an opening/closing valve, are installed in the source gas supply pipe 311 in this order from an upstream side. With this configuration, a source gas is supplied onto a surface of the wafer W from an upper side of the substrate mounting table 10 through the gas supply path 253 of the gas supply unit 25a to which the source gas supply pipe 311 is connected. The gas supply unit 25a connected to the source gas supply pipe 311 will be referred to as a “source gas supply unit”. That is, the source gas supply unit 25a is disposed above the substrate mounting table 10 and supplies a source gas onto the surface of the substrate W from the upper side of the substrate mounting table 10.

The source gas is one of the process gases supplied to the wafer W, and may be, for example, a source gas (i.e., a TiCl₄ gas) obtained by vaporizing TiCl₄ (titanium tetrachloride) that is a metal liquid source containing a titanium (Ti) element. The source gas may be any one of a solid, a liquid, and a gas at room temperature and normal pressure. When the source gas is a liquid at the room temperature and under the normal pressure, a vaporizer (not shown) may be installed between the source gas supply source 312 and the MFC 313. Herein, a source gas that is a gas at the room temperature and under the normal pressure will be described.

Further, a gas supply system (not shown) for supplying an inert gas acting as a carrier gas for a source gas may be connected to the source gas supply pipe 311. As the inert gas acting as a carrier gas, specifically, for example, a nitrogen (N₂) gas may be used. Further, in addition to the N₂ gas, for example, a noble gas such as a helium (He) gas, a neon (Ne) gas, or an argon (Ar) gas may be used.

In addition, in another gas supply pipe 25b arranged with the gas supply unit 25a to which the source gas supply pipe 311 is connected, with one gas supply unit 25c interposed therebetween, a reaction gas supply pipe 321 is connected to the gas supply path 253 of the gas supply unit 25b. A reaction gas supply source 322, a mass flow controller (MFC) 323 which is a flow rate controller (flow rate control unit), and a valve 324 which is an opening/closing valve are installed in the reaction gas supply pipe 321 in this order from the upstream side. With this configuration, a reaction gas is supplied onto a surface of the wafer W from an upper side of the substrate mounting table 10 through the gas supply path 253 of the gas supply unit 25b to which the reaction gas supply pipe 321 is connected. The gas supply unit 25b connected to the reaction gas supply pipe 321 will be referred to as a “reaction gas supply unit”. That is, the reaction gas supply unit 25b is disposed above the substrate mounting table 10 and supplies a reaction gas onto the surface of the substrate W from the upper side of the substrate mounting table 10.

Further, the “source gas supply unit” and the “reaction gas supply unit” may be collectively referred to as a “process gas supply unit” in the present disclosure. Further, any one of the “source gas supply unit” and the “reaction gas supply unit” may be referred to as a “process gas supply unit.

The reaction gas is another one of process gases supplied to the wafer W, and for example, an ammonia (NH₃) gas is used.

Further, a gas supply system (not shown) for supplying an inert gas acting as a carrier gas or a dilution gas for a reaction gas may be connected to the reaction gas supply pipe 321. As the inert gas acting as a carrier gas or a dilution gas, specifically, for example, it may be considered that an N₂ gas is used, but in addition to the N₂ gas, for example, a noble gas such as a He gas, a Ne gas, or an Ar gas may be used.

In addition, a plasma generating unit 40 described in detail later is installed in the gas supply unit 25b to which the reaction gas supply pipe 321 is connected. The plasma generating unit 40 serves to convert a reaction gas passing through the gas supply path 253 in the gas supply unit 25b into plasma.

The process gas supply unit is mainly configured by the source gas supply pipe 311, the source gas supply source 312, the MFC 313, the valve 314, the gas supply path 253 of the gas supply unit 25a to which the source gas supply pipe 311 is connected, the reaction gas supply pipe 321, the reaction gas supply source 322, the MFC 323, the valve 424, and the gas supply path 253 of the gas supply unit 25b to which the reaction gas supply pipe 321 is connected.

### (Inert Gas Supply Unit)

Regarding the gas supply unit 25c interposed between the gas supply unit 25a to which the source gas supply pipe 311 is connected and the gas supply unit 25b to which the reaction gas supply pipe 321 is connected, an inert gas supply pipe 331 is connected to the gas supply path 253 of the gas supply unit 25c. An inert gas supply source 332, a mass flow controller (MFC) 333 which is a flow rate controller (flow rate control unit), and a valve 334 which is an opening/closing valve are installed in the inert gas supply pipe 331 in this order from the upstream side. With this configuration, through the gas supply path 253 of the gas supply unit 25c to which the inert gas supply pipe 331 is connected, an inert gas is supplied onto the surface of the wafer W from an upper side of the substrate mounting table 10 at the side of each of the gas supply unit 25a to which the source gas supply pipe 311 is connected and the gas supply unit 25b to which the reaction gas supply pipe 321 is connected. The gas supply unit 25c connected to the inert gas supply pipe 331 will be referred to as an “inert gas supply unit”. That is, the inert gas supply unit 25c is disposed on the side of the source gas supply unit 25a or the reaction gas supply unit 25b to supply an inert gas onto the surface of the substrate W from the upper side of the substrate mounting table 10.

The inert gas acts as an air seal that seals a space between the upper surface of the wafer W and a lower surface of the gas supply unit 25c so that the source gas and the reaction gas do not coexist on the surface of the wafer W. Specifically, an N₂ gas may be used, for example. Further, in addition to the N₂ gas, for example, a noble gas such as a helium (He) gas, a neon (Ne) gas, an argon (Ar) gas may also be used.

The inert gas supply unit is mainly configured by the inert gas supply pipe 331, the inert gas supply source 332, the MFC 333, the valve 334, and the gas supply path 253 of the gas supply unit 25c to which the inert gas supply pipe 331 is connected.

### (Gas Exhaust Unit)

A gas exhaust pipe 341 is connected to an exhaust port 26 installed in the cartridge head 20. A valve 342 is installed in the gas exhaust pipe 341. Further, in the gas exhaust pipe 341, a pressure controller 343 for controlling an internal space of the external container part 22 of the cartridge head 20 to keep a predetermined pressure therein is installed at a downstream side of the valve 342. Further, in the gas exhaust pipe 341, a vacuum pump 344 is installed at a downstream side of the pressure controller 343.

With this configuration, the internal space of the external container part 22 is exhausted from the exhaust port 26 of the cartridge head 20. At this time, since the exhaust hole 231 is formed in the internal container part 23 of the cartridge head 20, and the inner side (i.e., the exhaust buffer chamber 255) of the internal container part 23 and an outer side (i.e., a space formed between the external container part 22 and the internal container part 23) communicate with each other. For that reason, when the exhausting operation is performed from the exhaust port 26, a gas flow is generated toward the side where the exhaust hole 231 is formed within the exhaust buffer chamber 255 (i.e., an outer peripheral side of the substrate mounting table 10), and a gas flow is also generated toward the interior of the exhaust buffer chamber 255 from the gas exhaust hole 254 (i.e., toward an upper side from the gas exhaust hole 254). Thus, the gases (i.e., the source gas, the reaction gas, or the inert gas) supplied onto the surface of the wafer W by the process gas supply unit or the inert gas supply unit are exhausted toward the upper side of the wafer W through the gas exhaust hole 254 and the exhaust buffer chamber 255 formed between the gas supply units 25, and are also exhausted to an outer side of the cartridge head 20 through the exhaust hole 231 and the exhaust port 26 from the interior of the exhaust buffer chamber 255.

The gas exhaust unit is mainly configured by the gas exhaust hole 254 and the exhaust buffer chamber 255 formed between the gas supply units 25, the exhaust hole 231, the exhaust port 26, the gas exhaust pipe 341, the valve 342, the pressure controller 343, and the vacuum pump 344.

### (Plasma Generating Unit)

The plasma generating unit 40 serves as an ICP coil for converting the reaction gas passing through the gas supply path 253 of the gas supply unit 25b into plasma. In order to convert the reaction gas into plasma, as illustrated in FIGS. 9A and 9B, the plasma generating unit 40 has a plasma generating chamber 410 as a flow path through which a reaction gas to be converted into plasma passes through within the gas supply path 253 of the gas supply unit 25b, and also has a plasma generating conductor 420 configured by a conductor disposed to surround the plasma generating chamber 410 on an outer periphery of the first member 251 in the gas supply unit 25b. That is, the reaction gas flowing within the plasma generating chamber 410 passes through the interior of the angular body formed by the plasma generating conductor 420. A cover (not shown) is installed therearound to prevent the plasma generating conductor 420 from being exposed to an atmosphere. Here, a description thereof will be omitted for the convenience of description.

The plasma generating conductor 420 is formed of a conductive material such as, for example, copper (Cu), nickel (Ni), or iron (Fe), and has a plurality of main conductor parts 521 extending along a mainstream direction of the reaction gas within the plasma generating chamber 410 and connection conductor parts 422 for electrically connecting the main conductor parts 421. That is, the conductor constituting the plasma generating conductor 420 includes a conductor portion as the main conductor parts 421 and a conductor portion as the connection conductor parts 422.

The plurality of main conductor parts 421 is each disposed to be arranged along a direction in which the side forming the corner portion 251a between the first member 251 and the second member 252 in the gas supply unit 25b extends. That is, the plurality of main conductor parts 521 is each disposed to be arranged from the rotation center side of the substrate mounting table 10 toward the outer peripheral side. Further, the main conductor parts 421 are each formed to have substantially the same length. Further, the connection conductor parts 422 include those disposed in positions connecting the lower ends of the main conductor parts 421 and those disposed in positions connecting the upper ends of the main conductor parts 521. Since having the main conductor parts 421 and the connection conductor parts 422 configured as described above, the plasma generating conductor 420 is disposed in a wave form waving in a mainstream direction of a gas within the plasma generating chamber 410 while surrounding the plasma generating chamber 410. A wavelength (period) and a wave height (amplitude) of the wave form are not particularly limited and may be appropriately determined in consideration of a size of the first member 251 of the gas supply unit 25b, a strength of a magnetic field to be generated in the plasma generating chamber 410 of the first member 251, or the like.

The input conductor 431 for providing power to the plasma generating conductor 420 is connected to one main conductor part 421, specifically, for example, one main conductor part 421 disposed on the outer peripheral side surface of the first member 251 of the gas supply unit 25b, among the plurality of main conductor parts 421, which is positioned in the conductor end of the plasma generating conductor 420. Further, the output conductor 432 for extracting power provided to the plasma generating conductor 420 is connected to another main conductor part 421, specifically, for example, another main conductor part 421 disposed on the outer peripheral side surface of the first member 251 of the gas supply unit 25b, among the plurality of main conductor parts 421, which is positioned in the conductor end of the plasma generating conductor 420.

In this manner, the input conductor 431 and the output conductor 432 are directly connected to the main conductor parts 421 constituting the plasma generating conductor 420. For that reason, it is possible to arrange the input conductor 431 and the output conductor 432 such that they extend as they are toward the upper side from the main conductor parts 421, that is, such that they extend along the outer peripheral side surface without having to secure a space between themselves and the outer peripheral side surface of the first member 251.

Among the input conductor 431 and the output conductor 432, an RF sensor 433, a high-frequency power source 434, and a frequency matcher 435 are connected to the input conductor 431. The high-frequency power source 434 supplies a high-frequency power to the plasma generating conductor 420 through the input conductor 431. The RF sensor 433 is installed at the output side of the high-frequency power source 434. The RF sensor 433 monitors information of a progressive wave or a reflected wave of a supplied high frequency. A reflective wave power monitored by the RF sensor 433 is input to the frequency matcher 435. Based on the information of the reflected wave monitored by the RF sensor 433, the frequency matcher 435 controls a frequency of high-frequency power supplied from the high-frequency power source 434 so that a reflected wave can be minimized. That is, the RF sensor 433, the high-frequency power source 434, and the frequency matcher 435 serve as a feeding part for supplying power to the plasma generating conductor 420.

Further, the edge of each of the input conductor 431 and the output conductor 432 is electrically grounded. Thus, the plasma generating conductor 420 is provided with electrically grounded ground parts at both ends thereof and is also provided with a feeding part for performing power supply between the ground parts.

The plasma generating unit 40 includes the plasma generating chamber 410, the plasma generating conductor 420, the input conductor 431, the output conductor 432, and a feeding part which is mainly configured by the RF sensor 433, the high-frequency power source 434, and the frequency matcher 435.

As described in detail later, in the plasma generating unit 40 having a configuration described above, a current having a high frequency is applied to the plasma generating conductor 420 through the input conductor 431 and the output conductor 432 to generate a magnetic field within the plasma generating chamber 410, thereby converting the reaction gas passing through the interior of the plasma generating chamber 410 into plasma. Thus, the reaction gas in a plasma state is supplied to a space below the gas supply unit 25b.

### (Controller)

Further, as illustrated in FIG. 2, the substrate processing apparatus according to the first embodiment includes a controller 50 that controls the operations of respective parts of the substrate processing apparatus. The controller 50 includes at least a computing unit 501 and a storage unit 502. The controller 50 is connected to each of the components described above to invoke a program or recipe from the storage unit 502 according to a higher controller or a user's instruction, and to control the operation of each component depending on the contents thereof. Specifically, the controller 50 controls the operations of the heater 11, the rotation driving mechanism 12, the RF sensor 433, the high-frequency power source 434, the frequency matcher 435, the MFCs 313 to 333, the valves 314 to 334 and 342, the pressure controller 343, the vacuum pump 344, and the like.

Further, the controller 50 may be configured by a dedicated computer or a general-purpose computer. For example, the controller 50 according to this embodiment may be configured by preparing an external storage device 51 that stores the program described above (e.g., a magnetic tape, a magnetic disc such as a flexible disc or a hard disc, an optical disc such as a compact disc (CD) or a digital versatile disc (DVD), a magneto-optical (MO) disc, or a semiconductor memory such as a universal serial bus (USB) memory or a memory card), and installing the program on the general-purpose computer using the external storage device 51.

Further, a means for supplying a program to the computer is not limited to the case of supplying the program through the external storage device 51. For example, the program may be supplied using a communication means such as the Internet or a dedicated line, rather than through the external storage device 51. Further, the storage unit 502 or the external storage device 51 is configured as a non-transitory computer-readable recording medium. Hereinafter, these will be collectively referred to simply as “a recording medium”. Further, when the term “recording medium” is used in the present disclosure, it may be understood as including the storage unit 502 only, the external storage device 51 only, or both of them.

### (3) Substrate Processing Process

Subsequently, as one of the processes of a method of manufacturing a semiconductor device, a process of forming a thin film on the wafer W using the substrate processing apparatus according to the first embodiment will be described. Further, in the following description, the operations of respective parts constituting the substrate processing apparatus are controlled by the controller 50.

Here, an example in which a TiCl₄ gas as a source gas (a first process gas) obtained by vaporizing TiCl₄ and an NH₃ gas as a reaction gas (a second process gas) are alternately supplied to form a TiN film as a metal thin film on the wafer W will be described.

### (Basic Processing Operation in Substrate Processing Process)

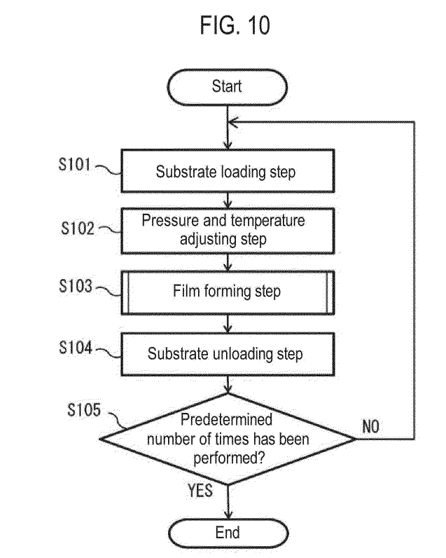

First, a basic processing operation in a substrate processing process of forming a thin film on the wafer W will be described. FIG. 10 is a flowchart illustrating a substrate processing process according to a first embodiment of the present disclosure.

### (Substrate Loading Step: S101)

In the substrate processing apparatus according to the first embodiment, first, in a substrate loading step (S101), a substrate loading/unloading port of a process vessel is opened, and a plurality of wafers W (for example, five wafers) is loaded into the process vessel by using a wafer moving conveyer (not shown) and is arranged and mounted on the substrate mounting table 10. Further, the waver moving conveyer is carried out of the process vessel, and the substrate loading/unloading port is closed to seal the interior of the process vessel.

### (Pressure and Temperature Adjusting Step: S102)

After the substrate loading step S101, a pressure and temperature adjusting step S012 is then performed. In the pressure and temperature adjusting step S102, after the interior of the process vessel is sealed in the substrate loading step S101, the gas exhaust system (not shown) connected to the process vessel is operated so that the interior of the process vessel is controlled to have a predetermined pressure. The predetermined pressure is a pressure at which a TiN film can be formed in a film forming step S103 described later, and is, for example, a process pressure having a degree at which a source gas supplied to the wafer W is not self-decomposed. Specifically, the process pressure may range from 50 to 5000 Pa. This process pressure is also maintained in the film forming step S103 described later.

Further, in the pressure and temperature adjusting step S102, power is supplied to the heater 11 embedded in the substrate mounting table 10 so that a surface of the wafer W is controlled to have a predetermined temperature. At this time, the temperature of the heater 11 is adjusted by controlling a condition of current applying to the heater 11 based on information of temperature detected by a temperature sensor (not shown). The predetermined temperature is a process temperature at which a TiN film can be formed in the film forming step S103 described later and is, for example, a process temperature having a degree at which the source gas supplied to the wafer W is not self-decomposed. Specifically, the process temperature may range from room temperature to 500 degrees C., and may range from room temperature to 400 degrees C. is some embodiments. The process temperature may also be maintained in the film forming step S103 described later.

### (Film Forming Step: S103)

After the pressure and temperature adjusting step S102, the film forming step S103 is then performed. A processing operation performed in the film forming step S103 roughly includes a relative position movement processing operation and a gas supply and exhaust processing operation. Details of the relative position movement processing operation and the gas supply and exhaust processing operation will be described later.

### (Substrate Unloading Step: S104)

After the film forming step S103, a substrate unloading step S104 is then performed. In the substrate unloading step S104, the processed wafer W is unloaded out of the process vessel by using the wafer moving conveyer in a reverse order of the case of the substrate loading step S101 described above.

### (Processing Number Determining Step: S105)

After the wafer W is unloaded, the controller 50 determines whether the number of times each of the steps of the substrate loading step S101, the pressure and temperature adjusting step S102, the film forming step S103, and the substrate unloading step S104 is performed have reached a predetermined number of times (S105). When it is determined that the number of times each step is performed have not reached the predetermined number of times, the process proceeds to the substrate loading step S101 in order to initiate the process for a next wafer W that waits for the process. Further, when it is determined that the number of times each step is performed have reached the predetermined number of times, a cleaning process is performed on the interior of the process vessel or the like as necessary, and the series of steps are then ended. The cleaning process may be performed by using a known technique, and thus, a description thereof will be omitted.

### (Relative Position Movement Processing Operation)

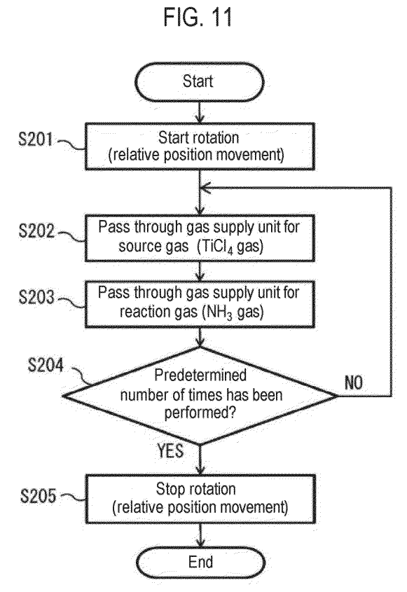

Next, a relative position movement processing operation performed in the film forming step S103 will be described. The relative position movement processing operation is a processing operation of rotating the substrate mounting table 10 to move a relative position between each wafer W mounted on the substrate mounting table 10 and the cartridge head 20. FIG. 11 is a flowchart illustrating details of the relative position movement processing operation performed in the film forming step of FIG. 10.

In the relative position movement processing operation performed in the film forming step S103, first, a relative position movement between the substrate mounting table 10 and the cartridge head 20 (S201) is started by rotating the substrate mounting table 10 by the rotation driving mechanism 12. Thus, each wafer W mounted on the substrate mounting table 10 sequentially passes through a lower side of each gas supply unit 25 constituting the cartridge head 20.

At this time, a gas supply and exhaust processing operation described in detail later is started in the cartridge head 20. Thus, a source gas (TiCl₄ gas) is supplied from the gas supply path 253 of a certain gas supply unit 25a, and a reaction gas (NH₃ gas) in a plasma state is supplied from the gas supply path 253 of another gas supply unit 25b arranged with the gas supply unit 25a with one gas supply unit 25c interposed therebetween. Hereinafter, the process gas supply unit including the gas supply path 253 through which a source gas is supplied will be referred to as a “source gas supply unit” and the process gas supply unit including the gas supply path 253 through which a reaction gas is supplied will be referred to as a “reaction gas supply unit”.

Herein, description will continue focusing on one particular wafer W. When the substrate mounting table 10 is started to rotate, the wafer W passes through a lower side of the gas supply path 253 in the source gas supply unit (S202). At this time, from the gas supply path 253, a source gas (a TiCl₄ gas) is supplied onto the surface of the wafer W. The supplied source gas is attached to the wafer W to form a source gas-containing layer. Further, a passage time during which the wafer W passes through the lower side of the gas supply path 253 of the source gas supply unit, i.e., a source gas supply time, has been adjusted to range from, for example, 0.1 to 20 seconds.

After the wafer W passes through the lower side of the gas supply path 253 of the source gas supply unit, the wafer W passes through a lower side of the gas supply unit 25c for supplying an inert gas (an N₂ gas) and subsequently passes through a lower side of the gas supply path 253 in the reaction gas supply unit (S203). At this time, from the gas supply path 253, a reaction gas (an NH₃ gas) in a plasma state is supplied onto the surface of the wafer W. The reaction gas in the plasma state is uniformly supplied onto the surface of the wafer W to react with the source gas-containing layer adsorbed on the wafer W to generate a TiN film on the wafer W. Further, a passage time during which the wafer W passes through the lower side of the gas supply path 253 of the reaction gas supply unit, i.e., a reaction gas supply time, has been adjusted to range from, for example, 0.1 to 20 seconds.

By setting the operation of passing through the lower side of the gas supply path 253 of the source gas supply unit and the operation of passing through the lower side of the gas supply path 253 of the reaction gas supply unit as one cycle, the controller 50 determines whether the cycle has been performed by a predetermined number of times (n cycle) (S204). When the cycle has been performed a predetermined number of times, a titanium nitride (TiN) film having a desired film thickness is formed on the wafer W. That is, in the film forming step S103, the cyclic processing operation of repeating the process of alternately supplying different process gases to the wafer W is performed by performing the relative position movement processing operation. Further, in the film forming step S103, a TiN film is formed on each wafer W simultaneously in parallel by performing the cyclic processing operation on each wafer W mounted on the substrate mounting table 10.

Further, when the cyclic processing operation is performed the predetermined number of times and is terminated, the controller 50 terminates the rotation of the substrate mounting table 10 by the rotation driving mechanism 12, thereby stopping the relative position movement between the substrate mounting table 10 and the cartridge head 20 (S205). Thus, the relative position movement processing operation is terminated. Further, when the cyclic processing operation performed by the predetermined number of times is terminated, the gas supply and exhaust processing operation is also terminated.

### (Gas Supply and Exhaust Processing Operation)

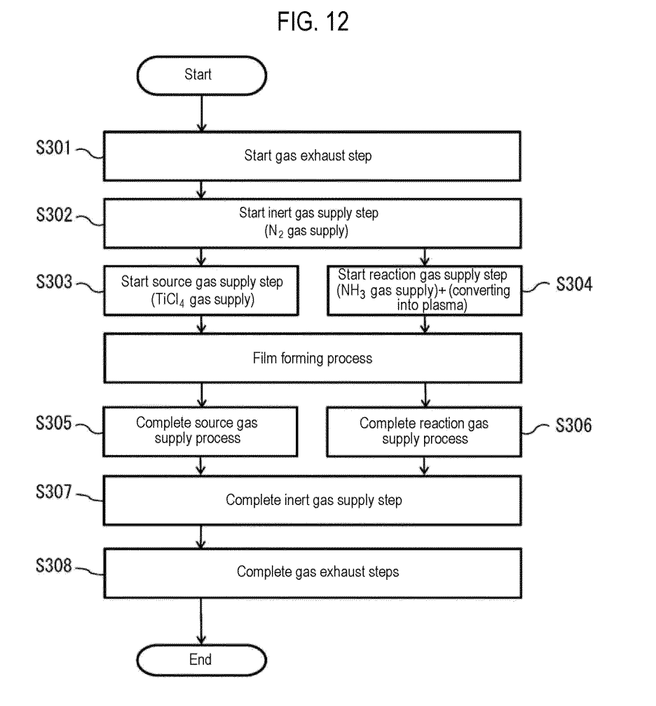

Subsequently, a gas supply and exhaust processing operation performed in the film forming step S103 will be described. The gas supply and exhaust processing operation is a processing operation that performs upward supply/upward exhaust of various gases with respect to the wafer W on the substrate mounting table 10. FIG. 12 is a flowchart illustrating details of the gas supply and exhaust processing operation performed in the film forming step of FIG. 10.

In the gas supply and exhaust processing operation performed in the film forming step S103, first, a gas exhaust step S301 is started. In the gas exhaust step S301, a valve 342 is opened, while operating a vacuum pump 344. Further, pressure in a space below the gas exhaust hole 254 formed between the gas supply units 25 is controlled to a predetermined pressure by the pressure controller 343. The predetermined pressure is lower than pressure of the space below each of the gas supply units 25. Thus, in the gas exhaust step S301, a gas of the space below each of the gas supply units 25 is exhausted out of the cartridge head 20 through the gas exhaust hole 254, the exhaust buffer chamber 255, the exhaust hole 231, a space between the internal container part 23 and the external container part 22, and an exhaust port 26.

After the gas exhaust step S301 is started, an inert gas supply step S302 is started. In the inert gas supply step S302, by opening the valve 334 in the inert gas supply pipe 331 and adjusting the MFC 333 such that a flow rate becomes a predetermined flow rate, the inert gas (N₂ gas) is supplied onto the surface of the wafer W from an upper side of the substrate mounting table 10 through the gas supply path 253 of the gas supply unit 25c to which the inert gas supply pipe 331 is connected. A supply flow rate of the inert gas ranges from, for example, 100 to 10000 sccm.

When the inert gas supply step S302 is performed, since the lower surface of the second member 252 of the gas supply unit 25c is parallel to the wafer W on the substrate mounting table 10, the inert gas (N₂ gas) erupted from the gas supply path 253 of the gas supply unit 25c is uniformly spread in the space between a lower surface of the second member 252 and an upper surface of the wafer W. Further, since the gas exhaust step S301 has been already started, the inert gas (N₂ gas) spread in the space between the lower surface of the second member 252 and the upper surface of the wafer W is exhausted from the gas exhaust hole 254 positioned at the edge of the second member 252 toward an upper side of the wafer W. Thus, an air curtain is formed by the inert gas in a space below the gas supply unit 25c to which the inert gas supply pipe 331 is connected.

After the inert gas supply step S302 is started, the source gas supply step S303 and the reaction gas supply step S304 are then started.

In the source gas supply step S303, a source TiCl₄ is vaporized to generate a source gas (i.e., TiCl₄ gas) (preliminary vaporization). The preliminary vaporization of the source gas may be performed in parallel with the aforementioned substrate loading step S101, the pressure and temperature adjusting step S102, and the like. This is because a predetermined time is required in order to stably generate a source gas.

Further, after the source gas is generated, in the source gas supply step S303, by opening the valve 314 in the source gas supply pipe 311 and adjusting the MFC 313 such that a flow rate becomes a predetermined flow rate, the source gas (TiCl₄ gas) is supplied onto the surface of the wafer W from an upper side of the substrate mounting table 10 through the gas supply path 253 of the gas supply unit 25a to which the source gas supply pipe 311 is connected. A supply flow rate of the source gas ranges from, for example 10, to 3000 sccm.

At this time, an inert gas (N₂ gas) may be supplied as the carrier gas of the source gas. In this case, a supply flow rate of the inert gas ranges from, for example, 10 to 5000 sccm.

When the source gas supply step S303 is performed, since the lower surface of the second member 252 of the gas supply unit 25a is parallel to the wafer W on the substrate mounting table 10, the source gas (TiCl₄ gas) erupted from the gas supply path 253 of the gas supply unit 25a is uniformly spread in the space between the lower surface of the second member 252 and the upper surface of the wafer W. Further, since the gas exhaust step S301 has been already started, the source gas (TiCl₄ gas) spread in the space between the lower surface of the second member 252 and the upper surface of the wafer W is exhausted from the gas exhaust hole 254 positioned at the edge of the second member 252 toward an upper side of the wafer W. Further, at this time, since the inert gas supply step S302 was started, an air curtain of the inert gas has been formed in the space below the adjacent gas supply unit 25c. For that reason, the source gas spreading to the space below the gas supply unit 25a is prevented from being leaked to the space below the adjacent gas supply unit 25c.

In addition, in the source gas supply step S303, the source gas supplied to the wafer W is exhausted toward an upper side from the gas exhaust hole 254. At this time, the source gas passing through the gas exhaust hole 254 is introduced and spread into the exhaust buffer chamber 255. That is, the source gas supplied onto the wafer W is exhausted through the gas exhaust hole 254 and the exhaust buffer chamber 255 in which the source gas stays for a while. For this reason, even when a difference in flow resistance of the source gas passing through the gas exhaust hole 254 due to the planar shape of the gas exhaust hole 254 exists between the inner and outer circumferences, by allowing the source gas to be exhausted to be temporarily stayed within the exhaust buffer chamber 255, a pressure difference between the inner and outer circumferences resulting from a difference in flow resistance may be alleviated in the space below the gas supply unit 25c. That is, irregularity of a gas exposure amount to the wafer W in the inner and outer circumferences resulting from the difference in pressure between the inner and outer circumferences may be suppressed, and as a result, the surface of the wafer W may be uniformly processed.

On the other hand, in the reaction gas supply step S304 performed in parallel with the source gas supply step S303, the valve 324 in the reaction gas supply pipe 321 is opened and the MFC 323 is also adjusted in order for a flow rate to be a predetermined value. Accordingly, a reaction gas (NH₃ gas) is supplied onto the surface of the wafer W from the upper side of the substrate mounting table 10 through the gas supply path 253 of the gas supply unit 25b to which the reaction gas supply pipe 321 is connected. A supply flow rate of the reaction gas (NH₃ gas) ranges from, for example, 10 to 10000 sccm.

At this time, an inert gas (N₂ gas) may be supplied as a carrier gas or a dilution gas of the reaction gas. In this case, a supply flow rate of the inert gas ranges from, for example, 10 to 5000 sccm.

Further, in the reaction gas supply step S304, the reaction gas (NH₃ gas) supplied onto the surface of the wafer W through the gas supply path 253 is converted into plasma. Specifically, a current having a high frequency is applied from the high-frequency power source 434 and the frequency matcher 435 through the input conductor 431 and the output conductor 432 while the RF sensor 433 is monitoring the plasma generating conductor 420. When the current is applied, a magnetic field is generated around the plasma generating conductor 420. At this time, the plasma generating conductor 420 is disposed to surround the plasma generating chamber 410 and is also configured to have the plurality of main conductor parts 421. That is, the plurality of main conductor parts 421 is equally arranged around the plasma generating chamber 410. For this reason, when a magnetic field is generated around the plasma generating conductor 420 by applying a current to the plasma generating conductor 420, a composite magnetic field compounded from magnetic fields by the main conductor parts 421 is formed within the plasma generating chamber 410, in a range of the region in which the plurality of main conductor parts 421 is disposed. When the reaction gas passes through the interior of the plasma generating chamber 410 in which the composite magnetic field is formed, the reaction gas is excited by the composite magnetic field so as to be converted into plasma. In this manner, in the reaction gas supply step S304, the reaction gas (NH₃ gas) passing through the plasma generating chamber 410 formed in the gas supply path 253 of the gas supply unit 25b is converted into plasma. Accordingly, the reaction gas (NH₃ gas) in a plasma state is supplied to the space below the gas supply unit 25b. Further, in the reaction gas supply step S304, since the reaction gas is converted into plasma by using the plurality of main conductor parts 421 which is equally arranged to surround the plasma generating chamber 410, there is less possibility that plasma generated within the plasma generating chamber 410 becomes non-uniform. In addition, since the reaction gas is converted into plasma by the inductively coupled method in which the composite magnetic field formed within the plasma generating chamber 410 is used, high density plasma can be easily obtained.

In the reaction gas supply step S304 described above, since the lower surface of the second member 252 in the gas supply unit 25b is parallel to the wafer W on the substrate mounting table 10, the reaction gas (NH₃ gas) in a plasma state erupted from the gas supply path 253 of the gas supply unit 25b is uniformly spread in the space between the lower surface of the second member 252 and the upper surface of the wafer W. Further, since the gas exhaust step S301 has been already started, the reaction gas (NH₃ gas) in a plasma state which has spread in the space between the lower surface of the second member 252 and the upper surface of the wafer W is exhausted from the gas exhaust hole 254 positioned at the edge of the second member 252 toward an upper side of the wafer W. Further, at this time, an air curtain has been formed by the inert gas by initiation of the inert gas supply step S302 in a space below the adjacent gas supply unit 25c. For this reason, the reaction gas in the plasma state spreading to the space below the gas supply unit 25 is not leaked to the space below the adjacent gas supply unit 25.

Further, in the reaction gas supply step S304, the reaction gas in the plasma state supplied to the wafer W is exhausted toward an upper side from the gas exhaust hole 254. At this time, the reaction gas in the plasma state passing through the gas exhaust hole 254 is introduced to the exhaust buffer chamber 255 and spread into the exhaust buffer chamber 255. That is, the reaction gas supplied onto the wafer W is exhausted through the gas exhaust hole 254 and the exhaust buffer chamber 255 in which the reaction gas stays for a while. For this reason, even when a difference in flow resistance of the reaction gas passing through the gas exhaust hole 254 due to the planar shape of the gas exhaust hole 254 exists between the inner and outer circumferences, by allowing the reaction gas to be exhausted to be temporarily stayed within the exhaust buffer chamber 255, a pressure difference between the inner and outer circumferences resulting from a difference in flow resistance may be alleviated in the space below the gas supply unit 25c. That is, lopsidedness of a gas exposure amount to the wafer W in the inner and outer circumferences resulting from the difference in pressure between the inner and outer circumferences may be suppressed, and as a result, the surface of the wafer W may be uniformly processed.

Further, a case where the buffer chamber 255 is provided has an increased exhaust efficiency from the gas exhaust hole 254 compared with a case in which the exhaust buffer chamber 255 is not present. Thus, a by-product such as a reaction inhibitor (for example, ammonium chloride) produced in the space below the gas supply unit 25 is efficiently discharged. That is, in the case where the exhaust buffer chamber 255 is installed, a reaction inhibitor or the like is effectively discharged, thereby restraining re-attachment to the wafer W or the like and improving film quality of the film formed on the wafer W.

The steps S301 to S304 described above are performed in parallel during the film forming step S103. However, the initiation timing thereof may be the foregoing order in order to enhance sealing characteristics by the inert gas, but the present disclosure is not limited thereto and the steps S301 to S304 may be simultaneously initiated.

By allowing the foregoing steps S301 to S304 to be performed in parallel, in the film forming step S103, each wafer W mounted on the substrate mounting table 10 sequentially passes through the space below the gas supply unit 25a for supplying the source gas (TiCl₄ gas) and the space below the gas supply unit 25b for supplying the reaction gas (NH₃ gas) in a plasma state. Further, since the gas supply unit 25c for supplying the inert gas (N2 gas) is interposed between the gas supply unit 25a for supplying the source gas and the gas supply unit 25b for supplying the reaction gas, there is no possibility that the source gas and the reaction gas supplied to each wafer W are mixed.

When the gas supply and exhaust processing operation is terminated, the source gas supply step is first terminated (S305) and the reaction gas supply step is terminated (S306). Further, after the inert gas supply step is terminated (S307), the gas exhaust step is terminated (S308). However, like the initiation timings described above, these steps S305 to S308 may be terminated at different timings or may be terminated simultaneously.

### (4) Effects of First Embodiment

According to the first embodiment, one or a plurality of effects given below is provided.

(a) According to the first embodiment, since the plasma generating unit 40 is installed in the gas supply unit 25b, it is possible to supply the reaction gas in the plasma state onto the surface of the wafer W in the reaction gas supply step S304. Thus, in the film forming step S103, the reaction efficiency of the reaction gas with the source gas-containing layer adsorbed on the wafer W may be increased, compared with the case in which the reaction gas is not in a plasma state, thereby effectively performing film formation on the surface of the wafer W.

(b) Further, according to the first embodiment, the plasma generating unit 40 for converting the reaction gas into plasma is configured to have the plasma generating conductor 420 disposed to surround the plasma generating chamber 410 serving as a flow path of the reaction gas. In addition, the plasma generating conductor 420 has the plurality of main conductor parts 421 extending along a mainstream direction of the gas within the plasma generating chamber 410 and the connection conductor parts 422 for electrically connecting the main conductor parts 421. That is, the plasma generating conductor 420 is disposed to surround the plasma generating chamber 410, wherein the plurality of main conductor parts 421 is disposed to be arranged around the plasma generating chamber 410.

With the plasma generating unit 40 having such a configuration, it is possible to arrange the input conductor 431 and the output conductor 432 such that they extend upwardly as they are from the main conductor parts 421 positioned in the conductor end of the plasma generating conductor 420. It is also possible to convert the reaction gas into plasma by providing power having a high frequency to the plasma generating conductor 420 using the input conductor 431 and the output conductor 432. For this reason, according to the first embodiment, in disposing the input conductor 431 and the output conductor 432, it is not required to secure a space between the conductors 431 and 431 and an outer peripheral side surface of the first member 251. That is, when compared with the comparative example of using the ICP coil (see FIG. 1B), a space can be easily saved. The first embodiment is very advantageous in that the plasma generating unit 40 can be disposed in a space saving manner, in particular, in the single-wafer-type substrate processing apparatus in which the source gas supply unit 25a, the inert gas supply unit 25c, the reaction gas supply unit 25b, and the inert gas supply unit 25c are disposed adjacent to each other in order.

Further, according to the first embodiment, the reaction gas flowing within the plasma generating chamber 410 is converted into plasma by an influence of a composite magnetic field formed in a range of a region in which the main conductor parts 421 of the plasma generating conductor 420 are disposed. That is, the composite magnetic field affects the reaction gas flowing within the plasma generating chamber 410 in a range of a region equivalent to a length of the main conductor parts 421. For this reason, it is possible to reliably convert a reaction gas into plasma compared with, for example, a case in which, although the conductor is disposed to surround the plasma generating chamber 410, the conductor is disposed simply in an annular shape without having the main conductor parts 421. Moreover, regarding the plasma generating conductor 420 forming a composite magnetic field, when the plurality of main conductor parts 421 is equally disposed to surround the plasma generating chamber 410, there is no possibility that plasma generated within the plasma generating chamber 410 becomes non-uniform. Further, in the first embodiment, since the reaction gas is converted into plasma by the inductively coupled method using the composite magnetic field formed within the plasma generating chamber 410, high density plasma can be easily obtained.

As described above, according to the first embodiment, since the plasma generating conductor 420 has a novel configuration different from that of the comparative example, the reaction gas can be converted into plasma in a space saving manner, while maintaining high plasma density.

(c) In addition, according to the first embodiment, the plasma generating conductor 420 surrounding the plasma generating chamber 410 is disposed to have a wave form waving in a mainstream direction of a gas within the plasma generating chamber 410. That is, the plasma generating conductor 420 is disposed such that the wave form is continuous over the entire circumference of the plasma generating chamber 410 and is also connected to each of the input conductor 431 and the output conductor 432 on the outer peripheral side surface of the first member 251. For this reason, even in a case in which the plasma generating conductor 420 is disposed to surround the plasma generating chamber 410, a configuration where only one input conductor 431 and one output conductor 432 are installed on the outer peripheral side surface of the first member 251 is possible, thereby suppressing the plasma generating unit 40 from being complicated in structure.

### Second Embodiment of the Present Disclosure

Subsequently, a second embodiment of the present disclosure will be described with reference to the drawings. Herein, however, the difference from the first embodiment described above will be mainly described and a description regarding other matters will be omitted.

### (Configuration of Substrate Processing Apparatus According to Second Embodiment)

In the substrate processing apparatus according to the second embodiment, a configuration of the plasma generating unit 40 is different from that of the first embodiment.

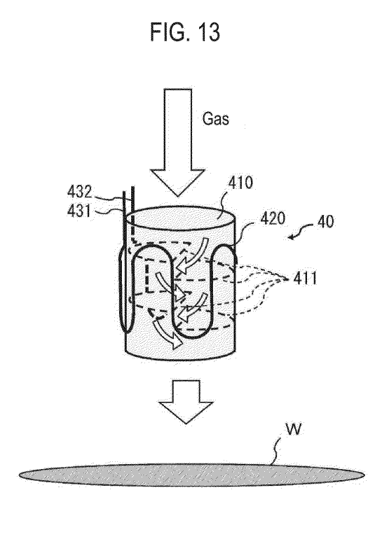

FIG. 13 is a schematic diagram illustrating a schematic configuration example of a plasma generating unit (ICP coil) according to a second embodiment. As in FIG. 1A, an outline of the configuration of the plasma generating unit 40 serving as an ICP coil in the second embodiment is schematically illustrated in the example shown in the drawing. Further, although the schematic diagram is illustrated for simplicity of description, when the plasma generating unit 40 constitutes the substrate processing apparatus in the second embodiment, the plasma generating unit 40 is used in a state where it is installed in the gas supply unit 25b (see FIGS. 9A and 9B).

In the plasma generating unit 40 described herein, a plurality of baffle plates 411 is installed within the plasma generating chamber 410 in order to control a flow direction of a reaction gas flowing within the plasma generating chamber 410. Each of the baffle plates 411 is formed as a semicircular plate-like member when viewed from the plane. Further, the baffle plates 411 are disposed within the plasma generating chamber 410 such that arc portions of the baffle plates 411 are oriented in different directions and such that the baffle plates 411 are arranged along a gas mainstream direction within the plasma generating chamber 410 at a predetermined interval.

In the plasma generating unit 40 having this configuration, a flow of a reaction gas within the plasma generating chamber 410 is blocked by the baffle plates 411 to show a serpentine flow. Thus, while approaching an inner wall surface of the plasma generating chamber 410, the reaction gas flows within the corresponding plasma generating chamber 410. At this time, a magnetic field has been formed by the plasma generating conductor 420 within the plasma generating chamber 410. Since the plasma generating conductor 420 is disposed to surround the plasma generating chamber 410, the magnetic field is stronger as it is positioned nearer to the inner wall surface of the plasma generating chamber 410. Thus, the reaction gas controlled in a flow direction by the baffle plates 411 is converted into plasma, while flowing in a region having the relatively strong magnetic field within the plasma generating chamber 410, and as a result, plasma density is increased, compared with a case in which the baffle plates 411 are not provided.

Further, the baffle plates 411 may also be referred to as a serpentine structure. Further, the plurality of baffle plates 411 may be collectively referred to as a serpentine part.

Here, the case in which the baffle plates 411 are formed to have a semicircular shape is taken as an example, but the shape of the baffle plates 411 is not particularly limited, as long as it can control a flow direction of the reaction gas within the plasma generating chamber 410. For example, a structure having a surface facing the gas flow which is inclined downwardly along a direction toward a downstream side may be possible. With this structure, the number of collisions between the plasma and the serpentine structure may be reduced, and thus, the plasma having high density can be more reliably maintained. Further, the number of the baffle plates 411 within the plasma generating chamber 410 is the same and is not particularly limited.

### (Effects of Second Embodiment)

According to the second embodiment, the following effects are provided.

(d) According to the second embodiment, since the baffle plates 411 are provided within the plasma generating chamber 410, it is possible to control a flow direction of the reaction gas flowing within the plasma generating chamber 410 and to allow the reaction gas to flow nearby the plasma generating conductor 420. Thus, plasma density of the reaction gas can be increased, compared with a case in which the baffle plates 411 are not provided.

### Third Embodiment of the Present Disclosure

Subsequently, a third embodiment of the present disclosure will be described with reference to the drawings. Here, however, the difference from the first embodiment described above will be mainly described and a description regarding other matters will be omitted.

### (Configuration of Substrate Processing Apparatus According to Third Embodiment)

In the substrate processing apparatus according to the third embodiment, a configuration of a plasma generating conductor 420a in the plasma generating unit 40 is different from that of the first embodiment.

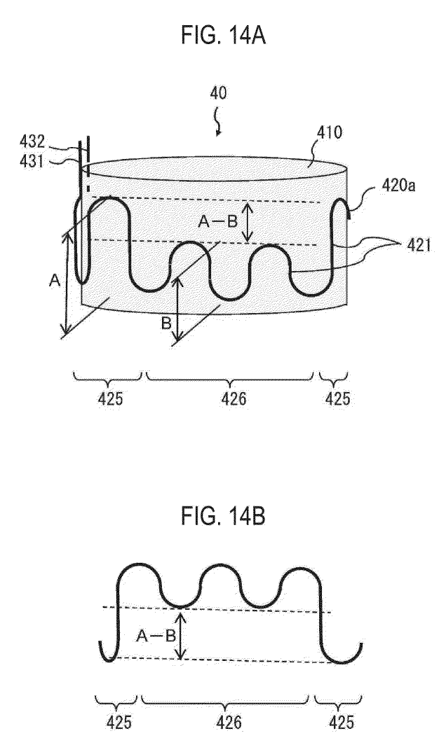

FIGS. 14A and 14B are schematic diagrams illustrating a schematic configuration example of a plasma generating unit (ICP coil) according to a third embodiment. As in FIG. 1A, an outline of the configuration of the plasma generating unit 40 serving as an ICP coil in the third embodiment is schematically illustrated in the example shown in the drawing. Further, although the schematic diagram is illustrated for simplicity of description, when the plasma generating unit 40 constitutes the substrate processing apparatus in the third embodiment, the plasma generating unit 40 is used in a state where it is installed in the gas supply unit 25b (see FIGS. 9A and 9B).

Like the first embodiment, the plasma generating conductor 420a described herein is disposed to have a wave form waving in a gas mainstream direction within the plasma generating chamber 410. However, the length of each of the main conductor parts 421 is different depending on positions, unlike the first embodiment. That is, the main conductor parts 421 are formed to have substantially the same length in the first embodiment. However, the plasma generating conductor 420a in the third embodiment has a region 425 in which the main conductor part 421 is long and a wave height (amplitude) of a wave form is A, and a region 426 in which the main conductor part 421 is short and a wave height (amplitude) of a wave form is B, as illustrated in FIG. 14A.

In the plasma generating unit 40 having such a configuration, a magnetic field exposure amount (a passage time, a passage distance, or the like) to the reaction gas passing through the interior of the plasma generating chamber 410 is different in the vicinity of the region 425 in which the main conductor part 421 is long and in the vicinity of the region 426 in which the main conductor part 421 is short. For this reason, plasma density of the reaction gas in a plasma state within the plasma generating chamber 410 differs. That is, when the reaction gas passes through the vicinity of the region 425 in which the main conductor part 421 is long, the plasma density is high, and when the reaction gas passes through the vicinity of the region 426 in which the main conductor part 421 is short, the plasma density is low. In other words, this means that a pitch of the plasma density of the reaction gas may be controlled depending on positions by differentiating the lengths of the main conductor parts 421 depending on positions, rather than being uniform.

Further, in the example illustrated in FIG. 14A, the case in which the region 425 and the region 426 of the plasma generating conductor 420a are disposed with respect to the lower side of the wave form, that is, the regions 425 and 426 are disposed such that the lower sides of the wave form are aligned, is illustrated. When the plasma generating conductor 420a is configured in this manner, a magnetic field is generated even in the region 426, e.g., a side close to the wafer W, and thus, a reaction gas supplied to the wafer W may be preferably converted into plasma. However, the plasma generating conductor 420a is not limited to the foregoing configuration and, as illustrated in FIG. 14B, the regions 425 and 426 may be disposed with respect to the upper side of the wave form.

### (Specific Example of Configuration)

Here, the configuration of the plasma generating conductor 420a in the third embodiment will be described in more detail.

Even in the third embodiment, the plurality of gas supply units 25 is radially disposed from the rotation center side of the substrate mounting table 10 toward an outer peripheral side. In the first member 251 of the gas supply unit 25b among the plurality of gas supply units 25, the plurality of main conductor parts 421 constituting the plasma generating conductor 420a is arranged from the rotation center side of the substrate mounting table 10 toward an outer peripheral side along the side forming the corner portion 251a of the gas supply unit 25b.

However, the planar shape of the gas supply path 253 of the gas supply unit 25b is not particularly limited and connection places of the reaction gas supply pipe 321 to the gas supply path 253 are not particularly limited either. For this reason, in some cases, an area in which the reaction gas may easily gather and an area in which the reaction gas is difficult to gather are generated within the plasma generating chamber 410 depending on the planar shape of the gas supply path 253, the position of the connection place of the reaction gas supply pipe 321, or the like in the gas supply unit 25b. The generation style of distribution deviation of the reaction gas can be estimated based on the planar shape of the gas supply path 253, the position of the connection area of the reaction gas supply pipe 321, or the like.

Specifically, for example, when the planar shape of the gas supply path 253 is a fan shape being widened along a direction toward the outer peripheral side of the substrate mounting table 10, it may be difficult for the reaction gas to gather in the rotation center side of the substrate mounting table 10 and it may be easy for the reaction gas to gather in the outer peripheral side of the substrate mounting table, due to an influence of gas conductance. Further, for example, even when the planar shape of the gas supply path 253 is a rectangular shape, the reaction gas may easily gather in a central portion of the planar shape of the gas supply path 253 and may be difficult to gather in the vicinity of the edge (in the vicinity of the wall surface) of the planar shape.

In contrast, in the plasma generating conductor 420a according to the third embodiment, even when a distribution deviation of the reaction gas occurs in the plasma generating chamber 410, the region 425 in which the main conductor part 421 is long and a wave height (amplitude) of a wave form has a size A can be disposed to correspond to the area in which the reaction gas easily gathers, and the region 426 in which the main conductor part 421 is short and a wave height (amplitude) of a wave form has a size B can be disposed to correspond to the area (for example, an edge of the outer peripheral side of the plasma generating chamber 410) in which the reaction gas is difficult to gather, depending on an estimated generation form of deviation.

Specifically, for example, in a case in which it is easy for the reaction gas to gather in the rotation center side of the substrate mounting table 10 while it is difficult for the reaction gas to gather in the outer peripheral side, the region 425 in which the main conductor part 421 is long and a wave height (amplitude) of a wave form has a size A is disposed at the rotation center side, whereas the region 426 in which the main conductor part 421 is short and a wave height (amplitude) of a wave form has a size B is disposed at the outer peripheral side. That is, the length of the main conductor part 421 at the rotation center side of the substrate mounting table 10 is formed shorter than that at the outer peripheral side. When the regions 425 and 426 are disposed in this manner, the plasma generating unit 40 is configured such that the plasma density at the rotation center side of the substrate mounting table 10 is lower than that of the outer peripheral side. Further, for example, in a case in which it is easy for the reaction gas to gather in the vicinity of the central portion of the planar shape of the gas supply path 253 and it is difficult for the reaction gas to gather in the vicinity of the edge (in the vicinity of the wall surface) of the planar shape, the region 425 in which the main conductor part 421 is long and a wave height (amplitude) of a wave form has a size A is disposed in the region including the center of a side forming the corner portion 251a of the gas supply unit 25b (i.e., in the vicinity of the center of the plasma generating chamber 410), whereas the region 426 in which the main conductor part 421 is short and a wave height (amplitude) of a wave form has a size B is disposed in the region including the edge of the above-described side (i.e., in the vicinity of the edge of the plasma generating chamber 410). That is, the length of the main conductor part 421 in the central portion of the plasma generating chamber 410 is formed longer than that at the edge side of the plasma generating chamber 410. When the regions 425 and 426 are disposed in this manner, the plasma generating unit 40 is configured such that the plasma density in the vicinity of the center of the plasma generating chamber 410 is higher than that of the edge side thereof.

Thus, according to the plasma generating unit 40 in the third embodiment, even in a case in which a distribution deviation of the reaction gas may occur within the plasma generating chamber 410, the plasma density of the place in which the reaction gas easily gathers can be increased and plasma density of the place in which the reaction gas is difficult to gather can be lowered, thereby reducing a possibility that the plasma generated within the plasma generating chamber 410 becomes not uniform.

### (Other Configuration Example)

In the foregoing description, the case in which the regions 425 and 426 of the plasma generating conductor 420a are disposed depending on whether the reaction gas can easily gather within the plasma generating chamber 410 is taken as an example, but the disposition of the regions 425 and 426 is not limited thereto.

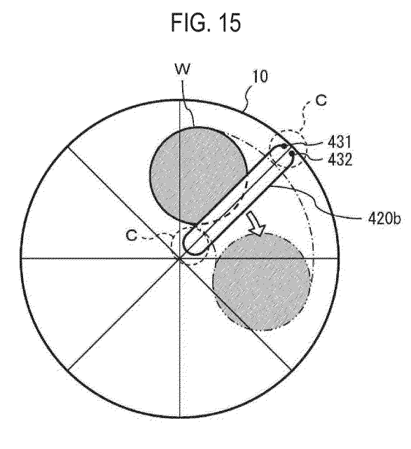

FIG. 15 is a schematic diagram illustrating another configuration example of the plasma generating unit according to the third embodiment. In the example shown in drawing, a planar shape of a plasma generating conductor 420b and the substrate mounting table 10 according to another configuration example of the third embodiment is schematically illustrated. The plasma generating conductor 420b of the example of the drawing has an oval planar shape extending in a diameter direction of the substrate mounting table 10 so as to surround the outer periphery of the first member 251 in the gas supply unit 25b.

In the plasma generating conductor 420b having such a configuration, when a width of the oval shape in a shorter diameter direction is reduced, plasma may concentrate on circular arc portions (portions “C” in the drawing) positioned in the vicinity of both ends of the oval shape in a lengthwise direction. This is because the plasma generating conductor 420b is rapidly folded back in the circular arc portions in the vicinity of both ends. Thus, when the planar shape is an oval shape, the region 426 in which the main conductor part 421 is short and a wave height (amplitude) of a wave form has a size B is disposed in the circular arc portions in the vicinity of both ends and the region 425 in which the main conductor part 421 is long and a wave height (amplitude) of a wave form has a size A is disposed in other portions (i.e., portions of the linear side constituting the oval), in the plasma generating conductor 420b. In this manner, the plasma density in the circular arc portions in the vicinity of both ends is lowered, so that the concentration of plasma on the vicinity of the corresponding both ends can be suppressed and thus, the uniformity of plasma in a diameter direction of the substrate mounting table 10 can be secured.

Further, in a case in which the planar shape of the plasma generating conductor 420b is an oval shape extending in the diameter direction of the substrate mounting table 10, it is preferred to establish a relationship between the plasma generating conductor 420b and the substrate mounting table 10 such that the wafer W on the substrate mounting table 10 does not pass through a lower side of the circular arc portions (portions “C” in the drawing) of the oval shape. This is because, even if the plasma is concentrated on the circular arc portions (portions “C” in the drawing), it is preferable that the concentration of plasma does not influence the wafer W on the substrate mounting table 10.

### (Another Configuration Example)

Further, in the foregoing descriptions, the case in which the plasma generating conductors 420a and 420b are divided into two regions, i.e., the region 425 in which the main conductor part 421 is long and the region 426 in which the main conductor part 421 is short is taken as an example, but in order to control a pitch of plasma density of the reaction gas by positions, the plasma generating conductors 420a and 420b may be divided into three or more regions.

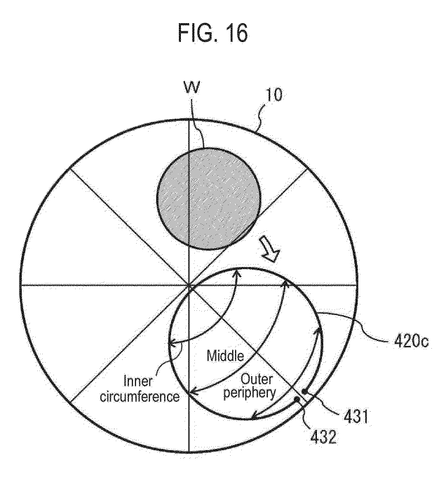

FIG. 16 is a schematic diagram illustrating another configuration example of the plasma generating unit according to the third embodiment. In the example shown in drawing, a planar shape of a plasma generating conductor 420c and the substrate mounting table 10 according to another configuration example of the third embodiment is schematically illustrated. The plasma generating conductor 420c of the example of the drawing has a circular planar shape which surrounds the outer periphery of the first member 251 of the gas supply unit 25b.

In the plasma generating conductor 420c having such a configuration, when the wafer W on the substrate mounting table 10 passes through the lower side of the plasma generating conductor 420c, passage distances of the wafer W are different at the inner circumferential side and the outer peripheral side of the plasma generating conductor 420c having a circular shape and at the middle of them. The difference in the passage distances may cause non-uniformity of the wafer W in the film forming process. Thus, when the planar shape is a circular shape, the plasma generating conductor 420c is divided into three or more regions, the regions are allocated to the inner circumferential side, the outer peripheral side, and the middle therebetween, respectively, and the lengths of the main conductor parts 421 are made different in each of the regions. In this manner, plasma density can be realized to satisfy the condition of the inner circumferential side < the middle < the outer peripheral side, thereby securing the uniformity of plasma with respect to the wafer W regardless of the difference in the passage distances of the wafer W.

### (Effects of Third Embodiment)

According to the third embodiment, the following effects are provided.

(e) According to the third embodiment, in the plasma generating conductors 420a, 420b, and 420c disposed to have a wave form waving in a gas mainstream direction within the plasma generating chamber 410, the length of each of the main conductor parts 421 is different depending on positions. Thus, for example, the region 425 in which the main conductor part 421 is long and a wave height (amplitude) of a wave form is large can be disposed in a position in which the reaction gas easily gathers, and the region 426 in which the main conductor part 421 is short and a wave height (amplitude) of a wave form is small can be disposed in a position in which the reaction gas is difficult to gather. Thus, it is possible to reduce a possibility that the plasma generated within the plasma generating chamber 410 becomes not uniform by controlling a pitch of plasma density of the reaction gas by positions.

(f) In particular, the third embodiment can be advantageously applied to a multi single-wafer-type substrate processing apparatus in which the gas supply units 25 are radially disposed from the rotation center side of the substrate mounting table 10 toward an outer peripheral side. This is because, in the gas supply unit 25b for supplying a reaction gas to the wafer W, for example, even in a case in which the reaction gas is difficult to gather at the rotation center side of the substrate mounting table 10 while being easy to gather at the outer peripheral side, the plasma density at the rotation center side can be adjusted to be lower than that of the outer peripheral side. As a result, it is possible to suppress the generation of the non-uniform plasma within the plasma generating chamber 410 and to enhance in-plane uniformity of the wafer W in the film forming process.

### Fourth Embodiment of the Present Disclosure

Subsequently, a fourth embodiment of the present disclosure will be described with reference to the drawings. Here, however, the difference from the first to third embodiments described above will be mainly described and a description regarding other matters will be omitted.

### (Configuration of Substrate Processing Apparatus According to Fourth Embodiment)

In the substrate processing apparatus according to the fourth embodiment, a configuration of a plasma generating conductor 420d in the plasma generating unit 40 is different from those of the first to third embodiments.

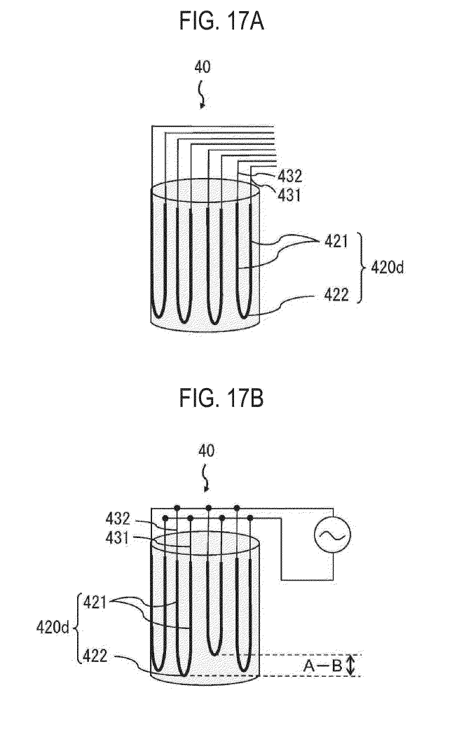

FIGS. 17A and 17B are schematic diagrams illustrating a configuration example of a plasma generating unit (ICP coil) used in a substrate processing apparatus according to a fourth embodiment. In the example shown in the drawing, an outline of a configuration of the plasma generating unit 40 serving as an ICP coil in the fourth embodiment is schematically illustrated, like FIG. 1A. Further, although the schematic diagram is illustrated for simplicity of description, when constituting the substrate processing apparatus in the fourth embodiment, the plasma generating unit 40 is used in a state where it is installed in the gas supply unit 25b (see FIGS. 9A and 9B).

As illustrated in FIG. 17A, in the plasma generating conductor 420d described herein, a plurality of main conductor parts 421 is arranged to configure the plasma generating conductor 420d as with the case of first embodiment. However, unlike the case of the first embodiment, the connection conductor parts 422 are only disposed in positions that connect lower ends of the main conductor parts 421. That is, the plasma generating conductor 420d of the fourth embodiment does not have the connection conductor parts 422 in positions that connect upper ends of the main conductor parts 421. Thus, the plasma generating conductor 420d has a structure obtained by dividing the wave form shown in the first embodiment into a plurality of U-shaped portions, that is, a structure of having a plurality of pairs of main conductor parts 421 connected by the connection conductor parts 422. Further, a height, width, and a disposition pitch of each of the U-shaped portions are not particularly limited and may be appropriately determined in consideration of a size of the first member 251 of the gas supply unit 25b, a strength of a magnetic field to be generated within the plasma generating chamber 410 of the first member 251, or the like.

Among the pair of main conductor parts 421 forming the U-shaped portion, an input conductor 431 for providing power is connected to one main conductor part 421. Further, an output conductor 432 for extracting a given power is connected to the other main conductor part 421. That is, the input conductor 431 and the output conductor 432 are connected to the U-shaped portion.

Further, in the plasma generating conductor 420d having such a configuration, when power is provided to each of the U-shaped portions through the input conductor 431 and the output conductor 432, a magnetic field is generated within the plasma generating chamber 410 to convert the reaction gas passing through the interior of the plasma generating chamber 410 into plasma.

At this time, since the plasma generating conductor 420d has a structure of being divided into a plurality of U-shaped portions and the U-shaped portions are individually disposed, it is possible to easily and individually control the distance of the U-shaped portions to the substrate mounting table 10. Further, even in a case in which a trouble such as breakdown occurs in the plasma generating conductor 420d, only the troubled U-shaped portion may be replaced, facilitating maintenance.

Further, in a structure in which the plasma generating conductor 420d is divided into a plurality of U-shaped portions, power can be individually supplied to each of the U-shaped portions by connecting different power supply systems or power control systems to each of the U-shaped portions. That is, even in a case in which the lengths of the plurality of main conductor parts 421 in the plasma generating conductor 420d are uniform, the plasma density in the vicinity of each of the U-shaped portions can be varied by individually controlling power provided to each of the U-shaped portions. Further, for example, it is possible to easily control the plasma density precisely and flexibly, compared with the case in which the lengths the main conductor part 421 are different as in the third embodiment.

However, the lengths of the main conductor parts 421 constituting the plasma generating conductor 420d may be different between the U-shaped portions as illustrated in FIG. 17B. In this case, like the case of the third embodiment, the plasma density can be controlled by the length of the main conductor part 421. Further, since plasma density is adjusted depending on the length of the main conductor part 421, it is not necessary to supply individual power to each of the U-shaped portions, and power may be uniformly supplied to each of the U-shaped portions. Thus, the complicated configuration of the power supply system or control system can be avoided, compared with the case in which power is individually supplied to each of the U-shaped portions.

### (Effects of Fourth Embodiment)

According to the fourth embodiment, the following effects are provided.

(g) According to the fourth embodiment, the connection conductor parts 422 are only disposed in positions that connect the lower ends of the main conductor parts 421 in the plasma generating conductor 420d, and the plasma generating conductor 420d includes a plurality of pairs of main conductor parts 421 connected by the connection conductor parts 422. That is, the plasma generating conductor 420d has a structure of being divided into a plurality of U-shaped portions. For this reason, it is possible to individually dispose the U-shaped portions, thus increasing a degree of freedom of disposition of the plasma generating conductor 420d and facilitating maintenance, compared with the cases of the first to third embodiments. In addition, it is possible to easily control a pitch of plasma density of a reaction gas by positions, thereby reducing a possibility that plasma generated within the plasma generating chamber 410 becomes non-uniform and enhancing in-plane uniformity of the wafer W in the film forming process.

### Fifth Embodiment of the Present Disclosure

Subsequently, a fifth embodiment of the present disclosure will be described with reference to the drawings. Herein, however, the difference from the first to fourth embodiments described above will be mainly described and a description regarding other matters will be omitted.

### (Configuration of Substrate Processing Apparatus According to Fifth Embodiment)

In the substrate processing apparatus according to the fifth embodiment, a configuration of the plasma generating unit 40 is different from those of the first to fourth embodiments.

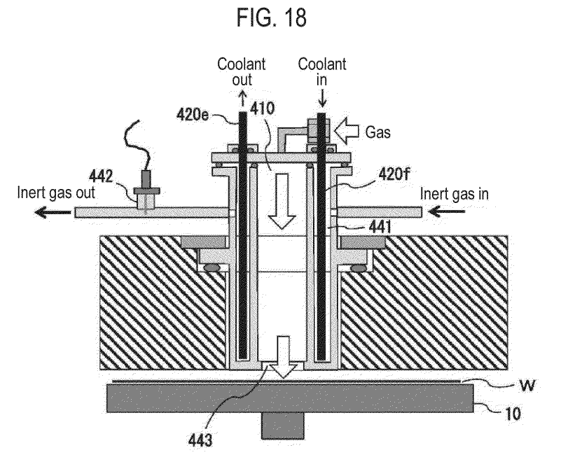

FIG. 18 is a side sectional view illustrating a schematic configuration example of a plasma generating unit (ICP coil) used in a substrate processing apparatus according to a fifth embodiment. Further, although the schematic diagram illustrating a side cross-section of the plasma generating unit 40 is employed for simplicity of description, when constituting the substrate processing apparatus in the fifth embodiment, the plasma generating unit 40 is used in a state where it is installed in the gas supply unit 25b (see FIGS. 9A and 9B).

In the example shown in the drawing, the plasma generating unit 40 has a plasma generating conductor 420e disposed to surround the plasma generating chamber 410 in which a reaction gas flows. The plasma generating conductor 420e has a plurality of main conductor parts 421 extending along a mainstream direction of the reaction gas within the plasma generating chamber 410 and connection conductor parts 422 for electrically connecting the main conductor parts 421. This is the same as that of the cases of the first to fourth embodiments.

However, unlike the cases of the first to fourth embodiments, the plasma generating conductor 420e described herein has a tubular shape and is made of a conductive material such as, for example, copper (Cu), nickel (Ni), or iron (Fe), wherein a coolant flows within the tube. When a coolant flows in the tube of the plasma generating conductor 420e, a temperature of the plasma generating conductor 420e is adjusted. That is, the plasma generating conductor 420e of the fifth embodiment has a temperature adjusting function for adjusting a temperature of the plasma generating conductor 420e.

Further, the plasma generating conductor 420e is disposed within a sealed space 441. Further, the sealed space 441 is configured such that an inert gas is supplied into the sealed space 441. As the inert gas, an N₂ gas may be considered to be used, but a He gas, a Ne gas, or an Ar gas may also be used. A temperature sensor 442 for measuring a temperature of the inert gas is installed in an exhaust path of the inert gas from the interior of the sealed space 441.

In the plasma generating unit 40 having such a configuration, during converting a reaction gas flowing within the plasma generating chamber 410 into plasma, a temperature of the inert gas exhausted from the interior of the sealed space 441 is measured by the temperature sensor 442 and a temperature of the plasma generating conductor 420e within the sealed space 441 is monitored. Further, a temperature is adjusted by allowing a coolant to flow into the tube of the plasma generating conductor 420e based on the monitoring result, so that the temperature of the plasma generating conductor 420e falls within a predetermined temperature range. That is, in the plasma generating unit 40 of the fifth embodiment, the temperature of the plasma generating conductor 420e is maintained within the predetermined temperature range by performing a feedback control based on the result of monitoring the temperature of the plasma generating conductor 420e.

When the temperature of the plasma generating conductor 420e is maintained within the predetermined temperature range through the feedback control, a variation in electric resistance in the plasma generating conductor 420e can be suppressed. Thus, a variation in plasma density can be restrained, thereby reducing a possibility that plasma generated within the plasma generating chamber 410 becomes non-uniform and enhancing in-plane uniformity of the wafer W in the film forming process. Further, a configuration in which, in a case where, e.g., a variation occurs in a film thickness of the wafer W in the film forming process notwithstanding a feedback control, it is determined that maintenance is necessary from an assumption that the plasma generating conductor 420e suffers from a problem, may be possible.

In addition, in the foregoing description, the case in which the temperature of the plasma generating conductor 420e is adjusted by allowing a coolant to flow into the tube of the plasma generating conductor 420e is taken as an example, but the temperature adjusting unit is not limited thereto and any other configuration may also be used. The other configuration may be, for example, the one that adjusts a temperature by using a gas flowing around the plasma generating conductor 420e. As for the gas flowing around the plasma generating conductor 420e, the inert gas as described above may be preferably used in that a change (for example, oxidation) in a surface state of the plasma generating conductor 420e may be restrained, but the gas is not limited to the inert gas and any other gas may also be used.

Moreover, in the foregoing description, the case in which the reaction gas converted into a plasma state within the plasma generating chamber 410 is supplied to the substrate W on the substrate mounting table 10 is taken as an example, but it may also be configured such that a plasma shielding plate (not shown) is installed at an exit part 443 of the plasma generating chamber 410 to form a so-called remote plasma. With this configuration, neutral radicals can be supplied.

### (Effects of Fifth Embodiment)

According to the fifth embodiment, the following effects are provided.

(h) According to the fifth embodiment, since the plasma generating conductor 420e has the function as a temperature adjusting unit for adjusting a temperature of the plasma generating conductor 420e, a temperature of the plasma generating conductor 420e can be maintained within the predetermined temperature range. Thus, a variation in electric resistance caused by a change in a temperature of the plasma generating conductor 420e can be suppressed, and thus, a variation in plasma density can also be restrained. That is, by suppressing a variation in temperature of the plasma generating conductor 420e, a possibility that plasma generated within the plasma generating chamber 410 becomes non-uniform can be reduce and in-plane uniformity of the wafer W in the film forming process can be enhanced.

### Other Embodiments of the Present Disclosure

While the embodiments of the present disclosure have been described in detail above, the present disclosure is not limited to the foregoing embodiments and various modifications may be made without departing from the teachings of the present disclosure.

For example, in the foregoing embodiments, the case in which the plasma generating unit 40 is installed in the gas supply unit 25b and a reaction gas supplied by the gas supply unit 25b to the wafer W is converted into plasma by the plasma generating unit 40 is taken as an example, but the present disclosure is not limited thereto. That is, the present disclosure is not limited to the reaction gas and may be applied to a case in which other gas is converted into plasma.

Further, for example, in the foregoing embodiments, the case in which a relative position between each wafer W on the substrate mounting table 10 and the cartridge head 20 is changed by rotating the substrate mounting table 10 or the cartridge head 20 is taken as an example, but the present disclosure is not limited thereto. That is, the rotational driving type described in the embodiments may not be necessarily used as long as a relative position between each wafer W on the substrate mounting table 10 and the cartridge head 20 is moved. For example, a direct type using a conveyer or the like may also be applied in the same manner.

Further, for example, in the foregoing embodiments, the inert gas supply unit 25c is installed between the source gas supply unit 25a and the reaction gas supply unit 25b, but the present disclosure is not limited thereto. For example, the inert gas supply unit 25c may be installed between two reaction gas supply units 25b. In this case, a supply structure for supplying a gas from a position other than the upper side of the wafer may be installed to supply a source gas to the process chamber, instead of the source gas supply unit 25a. For example, a source gas supply hole may be formed at the center of the process chamber to supply a source gas from the center of the process chamber.

Further, for example, in the foregoing embodiments, the inert gas supply unit 25c is installed between the source gas supply unit 25a and the reaction gas supply unit 25b, but the present disclosure is not limited thereto. For example, the inert gas supply unit 25c may be installed between two source gas supply units 25a. In this case, a supply structure for supplying a gas from a position other than the upper side of the wafer may be installed to supply a reaction gas to the process chamber, instead of the reaction gas supply unit 25b. For example, a reaction gas supply hole may be formed at the center of the process chamber to supply a reaction gas from the center of the process chamber.

Further, for example, in the foregoing embodiments, the case in which the TiCl₄ gas used as a source gas (a first process gas) and the NH₃ gas used as a reaction gas (a second process gas) are alternately supplied to form a TiN film on the wafer W as the film forming process performed by the substrate processing apparatus is taken as an example, but the present disclosure is not limited thereto. That is, the process gas used for the film forming process is not limited to the TiCl₄ gas, the NH₃ gas, or the like and any other types of gases may also be used to form different types of thin films. In addition, even in a case of using three or more types of process gases, the present disclosure can be applied as long as these gases are alternately supplied to perform the film forming process.

Further, for example, in the foregoing embodiments, the film forming process as the process performed by the substrate processing apparatus is illustrated as an example, but the present disclosure is not limited to thereto. That is, the present disclosure may also be applied to a process of forming an oxide film or a nitride film, or a process of forming a film including a metal, in addition to the thin film process. Further, the present disclosure may also appropriately applied to any other substrate process such as an annealing process, an oxidation process, a nitriding process, a diffusion process, or a lithography process, as well as the thin film process, regardless of the specific contents of the substrate process. Further, the present disclosure may also be applied to any other substrate processing apparatus such as, for example, an annealing processing apparatus, an oxidation processing apparatus, a nitriding processing apparatus, an exposure apparatus, a coating apparatus, a drying apparatus, a heating apparatus, or a processing apparatus using plasma. Further, the present disclosure may also be applied to any combination of these apparatuses. In addition, some of the components of a certain embodiment may be substituted with the components of other embodiment and the components of one embodiment may also be added to the components of other embodiment. Further, with respect to some of the components of each embodiment, other components may also be added, deleted, and substituted.

### Aspects of the Present Disclosure

Hereinafter, some aspects of the present disclosure will be supplementarily stated.

### (Supplementary Note 1)

According to one aspect of the present disclosure, there is provided a substrate processing apparatus, including:

a substrate mounting table on which a substrate is mounted;

a process chamber including the substrate mounting table;

a gas supply unit configured to supply a gas into the process chamber; and

a plasma generating unit configured to convert the gas supplied into the process chamber from the gas supply unit into a plasma state,

wherein the plasma generating unit includes:

a plasma generating chamber configured to serve as a flow path of the gas supplied into the process chamber from the gas supply unit; and

a plasma generating conductor configured by a conductor disposed to surround the plasma generating chamber, and

wherein the plasma generating conductor includes:

a plurality of main conductor parts extending along a mainstream direction of the gas within the plasma generating chamber; and

a plurality of connection conductor parts configured to electrically connect the plurality of main conductor parts.

### (Supplementary Note 2)

In the apparatus according to Supplementary Note 1, preferably, the plurality of connection conductor parts are disposed in positions connecting at least lower ends of the plurality of main conductor parts.

### (Supplementary Note 3)

In the apparatus according to Supplementary Note 1 or 2, preferably, the plasma generating conductor includes the plurality of main conductor parts and the connection conductor parts such that the plasma generating conductor is disposed to have a wave form waving in the mainstream direction of the gas within the plasma generating chamber.

### (Supplementary Note 4)

In the apparatus according to Supplementary Note 3, preferably, an input conductor configured to provide power to the plasma generating conductor is connected to one of the plurality of main conductor parts, and an output conductor configured to extract power provided to the plasma generating conductor is connected to another of the plurality of main conductor parts.

### (Supplementary Note 5)

In the apparatus according to Supplementary Note 1 or 2, preferably, the plasma generating conductor has a plurality of pairs of the plurality of main conductor parts connected by the plurality of connection conductor parts.

### (Supplementary Note 6)

In the apparatus according to Supplementary Note 5, preferably, an input conductor configured to provide power to the plasma generating conductor is connected to one of the plurality of main conductor parts constituting one of the plurality of pairs of the plurality of main conductor parts, and

an output conductor configured to extract power provided to the plasma generating conductor is connected to the other of the plurality of main conductor parts constituting one of the plurality of pairs of the plurality of main conductor parts.

### (Supplementary Note 7)

In the apparatus according to Supplementary Note 6, preferably, each of the input conductors connected to the plurality of pairs is individually connected to a power source, and

each of the output conductors connected to the plurality of pairs is individually connected to the power source.

### (Supplementary Note 8)

The apparatus according to any one of Supplementary Notes 1 to 7 preferably, the plasma generation chamber has a serpentine structure which controls a flow direction of the gas flowing within the plasma generation chamber.

### (Supplementary Note 9)

In the apparatus according to any one of Supplementary Notes 1 to 8, preferably, the substrate mounting table is configured to rotate in a state in which a plurality of substrates is circumferentially arranged on the substrate mounting table,

the process chamber and the gas supply unit are configured to sequentially supply gases converted into a plasma state in the plasma generating unit for each of the substrates on the substrate mounting table being rotated, and

the plurality of main conductor parts of the plasma generating conductor in the plasma generating unit are arranged from a rotation center side of the substrate mounting table toward an outer peripheral side.

### (Supplementary Note 10)

In the apparatus according to Supplementary Note 9, preferably, the plurality of main conductor parts arranged from the rotation center side of the substrate mounting table toward the outer peripheral side are configured to be different in length in a mainstream direction of the gas within the plasma generation chamber depending on arranged positions of the plurality of main conductor parts.

### (Supplementary Note 11)

In the apparatus according to Supplementary Note 9 or 10, preferably, the plasma generating unit is configured such that plasma density at the rotation center side is lower than that at the outer peripheral side.

### (Supplementary Note 12)

In the apparatus according to Supplementary Note 10 or 11, preferably, the lengths of the plurality of main conductor parts at the rotation center side are shorter than those of the outer peripheral side.

### (Supplementary Note 13)

The apparatus according to any one of Supplementary Notes 1 to 12, preferably, includes a temperature adjusting unit configured to adjust a temperature of the plasma generating conductor.

### (Supplementary Note 14)

According to another aspect of the present disclosure, there is provided a method of manufacturing a semiconductor device, the method including:

mounting a substrate on a substrate mounting table included in a process chamber;

converting a gas flowing within a plasma generating chamber into plasma, by using a plasma generating conductor configured by a conductor disposed to surround the plasma generating chamber serving as a flow path of the gas supplied into the process chamber, the plasma generating conductor having a plurality of main conductor parts extending along a mainstream direction of the gas within the plasma generating chamber and connection conductor parts for electrically connecting the main conductor parts; and

supplying a gas converted into a plasma state by the plasma generating conductor to the substrate on the substrate mounting table.

### (Supplementary Note 15)

According to still another aspect of the present disclosure, there is provided a program that causes a computer to perform a process, the process including:

mounting a substrate on a substrate mounting table included in a process chamber;

converting a gas flowing within a plasma generating chamber into plasma, by using a plasma generating conductor configured by a conductor disposed to surround the plasma generating chamber serving as a flow path of the gas supplied into the process chamber, the plasma generating conductor having a plurality of main conductor parts extending along a mainstream direction of the gas within the plasma generating chamber and connection conductor parts for electrically connecting the main conductor parts; and

supplying a gas converted into a plasma state by the plasma generating conductor to the substrate on the substrate mounting table.

### (Supplementary Note 16)

According to still another aspect of the present disclosure, preferably, there is provided a non-transitory computer-readable recording medium storing a program that causes a computer to perform a process, the process including:

mounting a substrate on a substrate mounting table included in a process chamber;

converting a gas flowing within a plasma generating chamber into plasma, by using a plasma generating conductor configured by a conductor disposed to surround the plasma generating chamber serving as a flow path of the gas supplied into the process chamber, the plasma generating conductor having a plurality of main conductor parts extending along a mainstream direction of the gas within the plasma generating chamber and connection conductor parts for electrically connecting the main conductor parts; and

supplying a gas converted into a plasma state by the plasma generating conductor to the substrate on the substrate mounting table.

According to the present disclosure in some embodiments, it is possible to form a high quality film using plasma.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a substrate mounting table on which a substrate is mounted;
a process chamber including the substrate mounting table;
a gas supply unit configured to supply a gas into the process chamber; and
a plasma generating unit configured to convert the gas supplied into the process chamber from the gas supply unit into a plasma state,
wherein the plasma generating unit includes:
a plasma generating chamber configured to serve as a flow path of the gas supplied into the process chamber from the gas supply unit; and
a plasma generating conductor configured by a conductor disposed to surround the plasma generating chamber, and
wherein the plasma generating conductor includes:
a plurality of main conductor parts extending along a mainstream direction of the gas within the plasma generating chamber; and
a plurality of connection conductor parts configured to electrically connect the plurality of main conductor parts with each other.

2. The apparatus of claim 1, wherein the plurality of connection conductor parts are disposed in positions connecting at least lower ends of the plurality of main conductor parts.

3. The apparatus of claim 2, wherein the plasma generating conductor comprises the plurality of main conductor parts and the connection conductor parts such that the plasma generating conductor is disposed to have a wave form waving in the mainstream direction of the gas within the plasma generating chamber.

4. The apparatus of claim 3, wherein an input conductor configured to provide power to the plasma generating conductor is connected to one of the plurality of main conductor parts, and
an output conductor configured to extract the power provided to the plasma generating conductor is connected to another of the plurality of main conductor parts.

5. The apparatus of claim 2, wherein the plasma generating conductor has a plurality of pairs of the plurality of main conductor parts connected by the plurality of connection conductor parts.

6. The apparatus of claim 2, further comprising a temperature adjusting unit configured to adjust a temperature of the plasma generating conductor.

7. The apparatus of claim 1, wherein the plasma generating conductor includes the plurality of main conductor parts and the connection conductor parts such that the plasma generating conductor is disposed to have a wave form waving in the mainstream direction of the gas within the plasma generating chamber.

8. The apparatus of claim 7, wherein an input conductor configured to provide power to the plasma generating conductor is connected to one of the plurality of main conductor parts, and
an output conductor configured to extract the power provided to the plasma generating conductor is connected to another of the plurality of main conductor parts.

9. The apparatus of claim 1, wherein the plasma generating conductor has a plurality of pairs of the plurality of main conductor parts connected by the plurality of connection conductor parts.

10. The apparatus of claim 9, wherein an input conductor configured to provide power to the plasma generating conductor is connected to one of the plurality of main conductor parts constituting one of the plurality of pairs of the plurality of main conductor parts, and
an output conductor configured to extract the power provided to the plasma generating conductor is connected to the other of the plurality of main conductor parts constituting one of the plurality of pairs of the plurality of main conductor parts.

11. The apparatus of claim 10, wherein each of the input conductors connected to the plurality of pairs is individually connected to a power source, and
each of the output conductors connected to the plurality of pairs is individually connected to the power source.

12. The apparatus of claim 9, further comprising a temperature adjusting unit configured to adjust a temperature of the plasma generating conductor.

13. The apparatus of claim 1, wherein the substrate mounting table is configured to rotate in a state in which a plurality of substrates is circumferentially arranged on the substrate mounting table,
the process chamber and the gas supply unit are configured to sequentially supply gases converted into a plasma state in the plasma generating unit for each of the substrates on the substrate mounting table being rotated, and
the plurality of main conductor parts of the plasma generating conductor in the plasma generating unit is arranged from a rotation center side of the substrate mounting table toward an outer peripheral side.

14. The apparatus of claim 13, wherein the plurality of main conductor parts arranged from the rotation center side of the substrate mounting table toward the outer peripheral side are configured to be different in length in the mainstream direction of the gas within the plasma generation chamber depending on arranged positions of the plurality of main conductor parts.

15. The apparatus of claim 14, wherein the plasma generating unit is configured such that plasma density at the rotation center side becomes lower than that at the outer peripheral side.

16. The apparatus of claim 15, wherein the lengths of the plurality of main conductor parts at the rotation center side are shorter than those at the outer peripheral side.

17. The apparatus of claim 14, wherein the plasma generation chamber has a serpentine structure which controls a flow direction of the gas flowing within the plasma generation chamber.

18. The apparatus of claim 13, wherein the plasma generating unit is configured such that plasma density at the rotation center side becomes lower than that at the outer peripheral side.

19. The apparatus of claim 18, wherein the lengths of the plurality of main conductor parts at the rotation center side are shorter than those at the outer peripheral side.

20. The apparatus of claim 13, further comprising a temperature adjusting unit configured to adjust a temperature of the plasma generating conductor.
